(19) United States
(12) Patent Application Publication
(10) Pub. No.: US 2014/0289208 A1
(43) Pub. Date: Sep. 25, 2014

(54) DATA COMPRESSION APPARATUS, DATA COMPRESSION METHOD, DATA DECOMPRESSION APPARATUS, AND DATA DECOMPRESSION METHOD

(71) Applicant: FUJITSU LIMITED, Kawasaki-shi (JP)

(72) Inventors: Noriko Itani, Hadano (JP); Yasuhiko Nakano, Kawasaki (JP); Takumi Maruyama, Yokohama (JP); RYUJI KAN, Yokohama (JP); Shigeki Itou, Kawasaki (JP)

(73) Assignee: FUJITSU LIMITED, Kawasaki-shi (JP)

(21) Appl. No.: 14/180,436

(22) Filed: Feb. 14, 2014

(30) Foreign Application Priority Data
Mar. 21, 2013 (JP) 2013-058644

(51) Int. Cl. H03M 7/30

(52) U.S. Cl. CPC H03M 7/30
USPC 707/693

(57) ABSTRACT

In a data compression apparatus, a search unit examines the sequence of symbols in compression target data, and searches for a second symbol string having the same sequence of symbols as a first symbol string that occurred previously, and a code generation unit encodes the second symbol string into a code containing information that specifies a block to which the beginning of the first symbol string belongs. In a data decompression apparatus, a code acquisition unit sequentially acquires codes from the beginning of the compressed data, and when the code of the second symbol string is acquired, a decompression unit acquires, from a storage device, one or more blocks starting with a block to which the beginning of the decompressed first symbol string belongs, on the basis of the information contained in the acquired code, and decompresses the second symbol string.

### CROSS-REFERENCE TO RELATED APPLICATION

This application is based upon and claims the benefit of priority of the prior Japanese Patent Application No. 2013-058644, filed on Mar. 21, 2013, the entire contents of which are incorporated herein by reference.

### FIELD

The embodiments discussed herein are related to a data compression apparatus, a data compression method, a data decompression apparatus, and a data decompression method.

### BACKGROUND

Apparatuses such as computers and the like often compress data when storing the data. Compressing data reduces the space needed to store the data. This allows for an efficient use of a storage device storing the data. Similarly, information communication apparatuses often compress data when transmitting the data. Compressing data reduces the amount of the data to be transmitted, and thus reduces the data transmission time.

There are generally two types of data compression techniques: lossless compression and lossy compression. Lossless compression is a technique that reduces the amount of data without any loss of data. On the other hand, lossy compression is a technique that compresses data at a high compression ratio while allowing some loss of data. Many types of data, such as text, programs, and the like, do not allow loss of data, and therefore are compressed by lossless compression.

Among lossless compression techniques, there is a technique that compresses a symbol string into a code called a Lempel-Ziv 77 (LZ77) code. LZ77 coding algorithm encodes a frequently occurring symbol string into a code indicating the position and length of the same symbol string that occurred previously. When decompressing data, each code is replaced with a symbol string that is specified by the position and the length indicated by the code.

There has been proposed a modification of LZ77 coding. This modified technique compresses the memory image of a personal computer or the like, and thereby reduces the processing time taken to store the memory image in a storage device such as a hard disk drive (HDD) or the like. According to this technique, when compressing the entire contents of the primary storage of a personal computer or the like and storing the compressed content in a storage device such as an HDD or the like, the shortest offset code is assigned to an offset that is spaced apart by (the word length of the central processing unit (CPU))÷(the processing unit length of compression (=symbol length)).

Further, there has been proposed a technique that performs encoding and decoding using repetition of data of at least two different sizes so as to enhance the compression ratio.

These techniques are disclosed, for example, in the following references:
Japanese Laid-open Patent Publication No. 2001-092627;
Japanese Laid-open Patent Publication No. 2002-043950; and
Noriko Itani, and Shigeru Yoshida, “Lossless Compression Technology and Patent; COMPRESSION SOFTWARE SLC/ELC ALGORITHMS”, C MAGAZINE, SOFTBANK Creative Corp, Sep. 18, 2004, Issue of October 2004, pp. 106-110.

In LZ77 coding, however, when decompressing data, a symbol string corresponding to a code is acquired from previously decompressed symbol strings in units of symbols. Therefore, the number of times of memory access is increased, so that decompression is not performed at high speed. For example, in the case where each symbol is represented by 1 byte, a symbol string corresponding to a code is acquired by repeatedly performing memory access in units of 1 byte. Since memory access takes time compared to operations in a register of the CPU, frequent memory access leads to an increase in the time taken to perform decompression.

Although the above description has discussed the problem with LZ77 coding, a similar problem occurs with other coding techniques that encode a symbol string into a code indicating the occurrence position and the length of the same symbol string that occurred previously. For example, a similar problem occurs with LZSS known as an improved version of LZ77.

### SUMMARY

According to one aspect of the invention, there is provided a data compression apparatus that includes a processor configured to perform a procedure including: dividing compression target data into a plurality of blocks each including two or more symbols, and examining a sequence of symbols in the data from a beginning thereof so as to search for a second symbol string having a same sequence of symbols as a first symbol string that occurred previously; and generating a code containing information that specifies a block to which a beginning of the first symbol string belongs, and encoding the second symbol string into the code.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an exemplary functional configuration of a system according to a first embodiment;

FIG. 2 illustrates an exemplary hardware configuration of a computer used in the first embodiment;

FIG. 3 illustrates association between a dictionary and symbols;

FIG. 4 illustrates exemplary data structures of codes;

FIG. 5 illustrates an example of a code for the case where a matching symbol string is present;

FIG. 6 illustrates an example of a code for the case where a matching symbol string is not present;

FIG. 7 illustrates an example of compressed data;

FIG. 8 is a block diagram illustrating functions for compressing and decompressing data;

FIG. 9 is a flowchart illustrating an exemplary procedure of a compression process;

FIG. 10 is a flowchart illustrating an exemplary procedure of a data decompression process;

FIG. 11 illustrates a decompression procedure using a register group;

FIG. 12 is a flowchart illustrating an exemplary procedure of a compression process using registers efficiently;

FIG. 13 is a flowchart illustrating an exemplary procedure of a decompression process using registers efficiently; and

FIG. 14 illustrates an example of compressed data.

### DESCRIPTION OF EMBODIMENTS

Several embodiments will be described below with reference to the accompanying drawings, wherein like reference numerals refer to like elements throughout. Features of different embodiments may be combined to form further embodiments without departing from the scope of the disclosure.

### (a) First Embodiment

First, a description will be given of a first embodiment. In the first embodiment, when decompressing compressed data, memory access is performed in units of a plurality of bytes. Thus, the number of times of memory access is reduced, and decompression is performed at high speed. For example, a computer may perform processing at high speed by performing memory access in units of a large data length. In particular, recent CPUs usually have a register of 32 bits (4 bytes) or 64 bits (8 bytes). Such a CPU is capable of directly storing large data, and performing operations such as copying and the like on the data in the register. Thus, by using a Single Instruction Multiple Data (SIMD) instruction, which processes multiple data streams with a single instruction, data is copied from the memory to a register in units of 16 bytes or 32 bytes. This allows high-speed data copying. Note that examples of instruction sets having SIMD instructions include Streaming SIMD Extensions (SSE).

However, if a determination of whether there is a matching symbol is made on a per-block basis in order to perform high-speed copying in units of blocks, the probability of match between symbols is reduced, so that the compression ratio is reduced. In view of this, in the first embodiment, while a determination of whether there is a matching symbol string is made on a per-symbol basis, encoding is performed such that memory access may be made in units of blocks upon decompression.

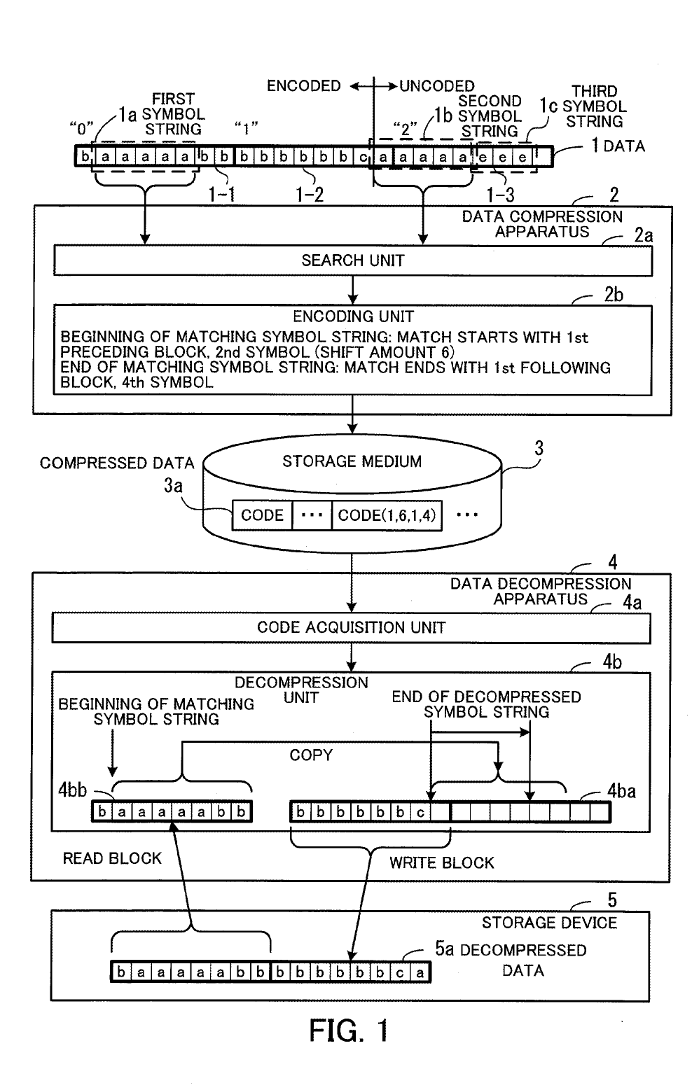

FIG. 1 illustrates an exemplary functional configuration of a system according to the first embodiment. In the first embodiment, a data compression apparatus 2, a storage medium 3, a data decompression apparatus 4, and a storage device 5 (memory) are provided for compression and decompression of data 1. The data compression apparatus 2 compresses the data 1 and stores compressed data 3a obtained by the compression in the storage medium 3. The data decompression apparatus 4 decompresses the data 1 on the basis of the compressed data 3a stored in the storage medium 3, and stores decompressed data 5a in the storage device 5. The storage device 5 stores the decompressed data 5a.

The data compression apparatus 2 includes a search unit 2a and an encoding unit 2b in order to compress the data 1. The search unit 2a divides the compression target data 1 into a plurality of blocks 1-1, 1-2, and 1-3, each including two or more symbols. For example, it is assumed that a processor for decompression processing performs high-speed data copying between memories in units of 1 block. In the example of FIG. 1, the blocks 1-1, 1-2, and 1-3 are indicated by the bold lines, and each block includes eight symbols. The address of the first block 1-1 is “0”; the address of the second block 1-2 is “1”; and the address of the third block 1-3 is “2”.

The search unit 2a examines the sequence of symbols in the data 1 from the beginning thereof, and searches for a second symbol string 1b having the same sequence of symbols as a first symbol string 1a that occurred previously. For example, the search unit 2a searches for the longest symbol string that matches a symbol string at the beginning of the uncoded portion, in the encoded portion of the data 1. In the example of FIG. 1, a string that matches the second symbol string 1b is a string of 5 symbols “aaaaa” starting with the second symbol of the immediately preceding block. That is, the symbol string found in the encoded portion is the first symbol string 1a, and the symbol string having the same sequence of symbols in the uncoded portion is the second symbol string 1b.

The encoding unit 2b generates a code containing information that specifies the block to which the beginning of the first symbol string 1a belongs, and encodes the second symbol string 1b into the code. For example, the encoding unit 2b calculates the difference between the address “0” of the block 1-1 to which the beginning of the first symbol string 1a belongs and the address “1” of the block 1-2 to which the beginning of the second symbol string 1b belongs. This difference represents the beginning of the first symbol string 1a determined by the relative number of blocks from the beginning of the second symbol string 1b. Then, the encoding unit 2b sets the value of the difference obtained by the calculation as the information that specifies the block 1-1 to which the beginning of the first symbol string 1a belongs.

The encoding unit 2b may store, in the code, information indicating the position of the beginning of the first symbol string 1a in the block. For example, the encoding unit 2b may store, in the code of the second symbol string 1b, the shift amount between the position of the beginning of the first symbol string 1a in its block and the position of the beginning of the second symbol string 1b in its block (the number of bytes to shift). In the example of FIG. 1, the beginning of the first symbol string 1a is the second symbol of the block 1-1, and the beginning of the second symbol string 1b is the eighth symbol of the block 1-2. Thus, the shift amount is “6”.

The encoding unit 2b may store, in the code of the second symbol string 1b, the difference between the address “1” of the block 1-2 to which the beginning of the second symbol string 1b belongs and the address “2” of the block 1-3 to which the last symbol of the second symbol string 1b belongs (the number of blocks to store), for example. In the example of FIG. 1, the difference is “1”.

The encoding unit 2b may store, in the code of the second symbol string 1b, the difference between the beginning position of the block 1-3 to which the last symbol of the second symbol string 1b belongs and the position of the last symbol of the second symbol string 1b in the block 1-3 (the number of bytes to store), for example. In the example of FIG. 1, the last symbol of the second symbol string 1b is the fourth symbol of the block 1-3. Thus, the difference is “4”.

Further, the encoding unit 2b may generate, for a third symbol string 1c for which a symbol string having the same sequence of symbols as the third symbol string 1c is not found in the previously examined portion, a code that contains information indicating that a matching symbol string is not present, for example. In this case, the encoding unit 2b generates compressed data 3a that contains the code of the second symbol string 1b, the code of the third symbol string 1c, and a copy of the third symbol string 1c.

Further, the encoding unit 2b calculates the difference between the position of the beginning of the third symbol string 1c in the block 1-3 of the data 1 and the position of the beginning of the copy of the third symbol string 1c in one of a plurality of blocks into which the compressed data 3a is divided, for example. The encoding unit 2b may store the calculated difference in the code of the third symbol string 1c.

The encoding unit 2b may store, in the code of the third symbol string 1c, the difference between the address “2” of the block 1-3 to which the beginning of the third symbol string 1c belongs and the address “2” of the block 1-3 to which the last symbol of the third symbol string 1c belongs, for example.

The encoding unit 2b may store, in the code of the third symbol string 1c, the difference between the beginning position of the block 1-3 to which the last symbol of the third symbol string 1c belongs and the position of the last symbol of the third symbol string 1c in the block 1-3, for example.

The data decompression apparatus 4 includes a code acquisition unit 4a and a decompression unit 4b so as to decompress the compressed data 3a stored in the storage medium 3.

The code acquisition unit 4a sequentially acquires codes from the beginning of the compressed data 3a. The code acquisition unit 4a transmits the acquired codes to the decompression unit 4b.

The decompression unit 4b sequentially decompresses the acquired codes to the original symbol strings, and stores the decompressed symbol strings in the storage device 5 in units of blocks. When the code of the second symbol string 1b is acquired, the decompression unit 4b acquires, from the storage device 5, one or more blocks starting with a block to which the beginning of the decompressed first symbol string 1a belongs, on the basis of the information that specifies the block to which the beginning of the first symbol string 1a belongs. Then, the decompression unit 4b copies the first symbol string 1a from the one or more blocks so as to decompress the second symbol string 1b.

As mentioned above, the code of the second symbol string 1b may contain the difference between the address “0” of the block 1-1 to which the beginning of the first symbol string 1a belongs and the address “1” of the block 1-2 to which the beginning of the second symbol string 1b belongs. In the case where this difference is contained, the decompression unit 4b acquires, from the storage device 5, one or more blocks starting with a block at an address preceding the address of the block to which the decompressed second symbol string belongs by the difference indicated by the code of the second symbol string 1b.

Further, the code of the second symbol string 1b may contain the shift amount between the position of the beginning of the first symbol string 1a in its block and the position of the beginning of the second symbol string 1b in its block. In the case where this difference is contained, the decompression unit 4b shifts the symbols of the first symbol string in the block acquired from the storage device 5 by the shift amount so as to merge the first symbol string and an immediately previously decompressed symbol string.

Further, the code of the second symbol string 1b may contain the difference between the address of the block to which the beginning of the second symbol string 1b belongs and the address of the block to which the last symbol of the second symbol string 1b belongs. In the case where this difference is contained, when the second symbol string 1b is decompressed, the decompression unit 4b stores the number of blocks indicated by the difference in the storage device 5.

Further, the code of the second symbol string 1b may contain the difference between the beginning position of the block to which the last symbol of the second symbol string 1b belongs and the position of the last symbol of the second symbol string 1b in this block. In the case where this difference is contained, when the second symbol string is decompressed, the decompression unit 4b holds a portion of the decompressed symbol string corresponding to the difference, from the end thereof. Then, the decompression unit 4b connects a symbol string that is decompressed on the basis of the next acquired code to the end of the held portion of the symbol string.

The compressed data 3a contains the code of the third symbol string 1c for which a symbol string that has the same sequence of symbols as the third symbol string 1c is not found in the previously examined portion, and a copy of the third symbol string 1c. Thus, when the code of the third symbol string 1c is acquired, the decompression unit 4b acquires the copy of the third symbol string 1c from the compressed data 3a in units of blocks. Then, as in the case of decompression of the second symbol string 1b, the decompression unit 4b performs processing such as copying the symbol string and the like so as to decompress the third symbol string 1c.

According to the system described above, the second symbol string 1b in the compression target data 1 is encoded into four values, for example. The first value is the difference between the address “0” of the block 1-1 to which the beginning of the first symbol string 1a belongs and the address “1” of the block 1-2 to which the beginning of the second symbol string 1b belongs (the relative number of blocks). The second value is the shift amount between the position of the beginning of the first symbol string 1a in its block and the position of the beginning of the second symbol string 1b in its block (the number of bytes to shift). The third value is the difference between the address “1” of the block 1-2 to which the beginning of the second symbol string 1b belongs and the address “2” of the block 1-3 to which the last symbol of the second symbol string 1b belongs (the number of blocks to store). The fourth value is the difference between the beginning position of the block 1-3 to which the last symbol of the second symbol string 1b belongs and the position of the last symbol of the second symbol string 1b in the block 1-3 (the number of bytes to store).

Further, the third symbol string 1c in the compression target data 1 is encoded into four values, for example. The first value is information indicating that a matching symbol string is not present. The second value is the difference between the position of the beginning of the third symbol string 1c in the block 1-3 of the data 1 and the position of the beginning of the copy of the third symbol string 1c in one of a plurality of blocks of the compressed data 3a to which the beginning of the copy of the third symbol string 1c belongs (the number of bytes to shift). The third value is the difference between the address “2” of the block 1-3 to which the beginning of the third symbol string 1c belongs and the address of the block 1-3 to which the last symbol of the third symbol string 1c belongs (the number of blocks to store). The fourth value is the difference between the beginning position of the block 1-3 to which the last symbol of the third symbol string 1c belongs and the position of the last symbol of the third symbol string 1c in the block 1-3 (the number of bytes to store).

Upon decompressing data, the decompression unit 4b performs decompression using a register 4ba that temporarily stores a byte string shorter than one block, for example. At the point immediately before decompression of the code of the second symbol string 1b, 7 bytes “bbbbbbc” are stored in the register 4ba. From the code (1, 6, 1, 4), the relative number of blocks “1”, the number of bytes to shift “6”, the number of blocks to store “1”, and the number of bytes to store “4” are obtained. Then, the decompression unit 4b acquires the block immediately preceding the block at the current position, and stores the acquired block in another register 4bb. Thus, a symbol string “baaaaabb” is stored in the register 4bb. The decompression unit 4b shifts the symbol string of the acquired block to the right by 6 bytes. Then, the beginning of “baaaaabb” is located at the position of the sixth byte. Then, the decompression unit 4b copies the symbols in the register 4bb to the position in the register 4ba corresponding to the shifted position. In this step, symbols are not copied to a region where symbols are already stored in the register 4ba. Thus, a symbol string “aaaaabb” starting with the second symbol of the symbol string in the register 4bb is connected to the end of “bbbbbbc” in the register 4ba.

Then, the decompression unit 4b stores one block in the storage device 5, on the basis the number of blocks to store “1”. The stored block is added to the end of the decompressed data 5a. Further, the decompression unit 4b recognizes the end of the decompressed symbol string as the fourth byte of the next block, on the basis of the number of bytes to store “4”.

Since a symbol string is encoded into such a code, it is possible to access the storage device 5 in units of blocks on the basis of the relative number of blocks and the number of blocks to store, when decompressing data. Thus, decompression may be performed at high-speed. Further, since the shift amount between a repeat start position in a copy source block and a repeat start position in the copy destination block (the number of bytes to shift) and the number of bytes less than one block (the number of bytes to store) are contained in the code, it is possible to determine whether there is a matching symbol string in units of bytes. This prevents a reduction in the data compression ratio.

Upon storing the compressed data 3a in the storage medium 3, the encoding unit 2b may divide the compressed data 3a into a plurality of blocks and store the codes and the copy of the third symbol string 1c in different blocks. This allows the data decompression apparatus 4 to read the compressed data 3a in units of blocks. Thus, data decompression may be performed at higher speed.

The search unit 2a and the encoding unit 2b may be realized by the processor of the data compression apparatus 2, for example. The code acquisition unit 4a and the decompression unit 4b may be realized by the processor of the data decompression apparatus 4, for example.

The lines connecting the components of FIG. 1 represent some of communication paths. Communication paths other than those of FIG. 1 may be provided.

### (b) Second Embodiment

Next, a description will be given of a second embodiment. In the second embodiment, upon decompressing data, data corresponding to a code may be copied by shifting data within a register. Thus, the processing efficiency is improved.

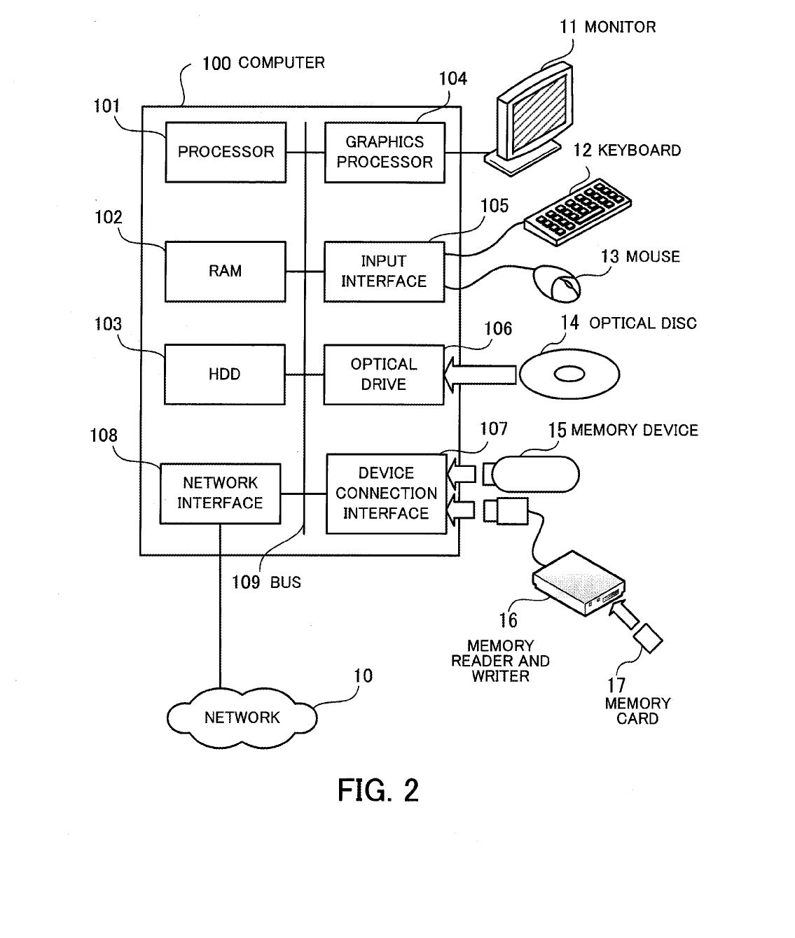

FIG. 2 illustrates an exemplary hardware configuration of a computer 100 used in the present embodiment. The entire operation of the computer 100 is controlled by a processor 101. A random access memory (RAM) 102 and a plurality of peripheral devices are connected to the processor 101 via a bus 109. The processor 101 may be a multiprocessor. Examples of the processor 101 include a CPU, a micro processing unit (MPU), a digital signal processor (DSP), and the like. The functions of the processor 101 may be implemented wholly or partly by using electronic circuits such as an application-specific integrated circuit (ASIC), a programmable logic device (PLD), and the like.

The RAM 102 serves as a primary storage device of the computer 100. The RAM 102 temporarily stores at least part of the operating system (OS) program and application programs that are executed by the processor 101. The RAM 102 also stores various types of data used for processing performed by the processor 101.

The peripheral devices connected to the bus 109 include an HDD 103, a graphics processor 104, an input interface 105, an optical drive 106, a device connection interface 107, and a network interface 108.

The HDD 103 magnetically writes data to and reads data from its internal disk. The HDD 103 serves as a secondary storage device of the computer 100. The HDD 103 stores the OS programs, application programs, and various types of data. Note that a semiconductor storage device such as a flash memory may be used as a secondary storage device.

A monitor 11 is connected to the graphics processor 104. The graphics processor 104 displays an image on the screen of the monitor 11 in accordance with a command from the processor 101. Examples of the monitor 11 include a display device using a cathode ray tube (CRT) and a liquid crystal display device.

A keyboard 12 and a mouse 13 are connected to the input interface 105. The input interface 105 receives signals from the keyboard 12 and the mouse 13, and transmits the received signals to the processor 101. The mouse 13 is an example of a pointing device, and other types of pointing devices may also be used. Examples of other types of pointing devices include a touch panel, a tablet, a touch pad, a track ball, and the like.

The optical drive 106 reads data from an optical disc 14 by using laser beams or the like. The optical disc 14 is a portable storage medium and stores data such that the data may be read through optical reflection. Examples of the optical disc 14 include digital versatile disc (DVD), DVD-RAM, compact disc read only memory (CD-ROM), CD-Recordable (CD-R), CD-Rewritable (CD-RW), and the like.

The device connection interface 107 is a communication interface that connects peripheral devices to the computer 100. For example, a memory device 15 and a memory reader and writer 16 may be connected to the device connection interface 107. The memory device 15 is a recording medium having a function to communicate with the device connection interface 107. The memory reader and writer 16 is a device that writes data to and reads data from a memory card 17. The memory card 17 is a card-type recording medium.

The network interface 108 is connected to a network 10. The network interface 108 exchanges data with other computers or communication apparatuses via the network 10.

With the hardware configuration described above, it is possible to realize the processing functions of the second embodiment. Note that, the apparatus of the first embodiment may be realized with a hardware configuration similar to that of the computer 100 of FIG. 2.

The computer 100 realizes the processing functions of the second embodiment by executing a program stored in a computer-readable recording medium, for example. The program describing the procedure to be performed by the computer 100 may be stored in various recording media. For example, the program to be executed by the computer 100 may be stored in the HDD 103. The processor 101 loads at least part of the program from the HDD 103 into the RAM 102 so as to execute the program. The program to be executed by the computer 100 may also be stored in a portable recording medium, such as the optical disc 14, the memory device 15, the memory card 17, and the like. The program stored in the portable recording medium may be executed after being installed into the HDD 103 under the control of the processor 101, for example. Further, the processor 101 may execute the program by reading the program directly from the portable recording medium.

The computer 100 having the configuration described above performs compression and decompression of data. Now, an encoding system in the second embodiment will be described. In the second embodiment, encoding is performed using already encoded symbol strings as a dictionary.

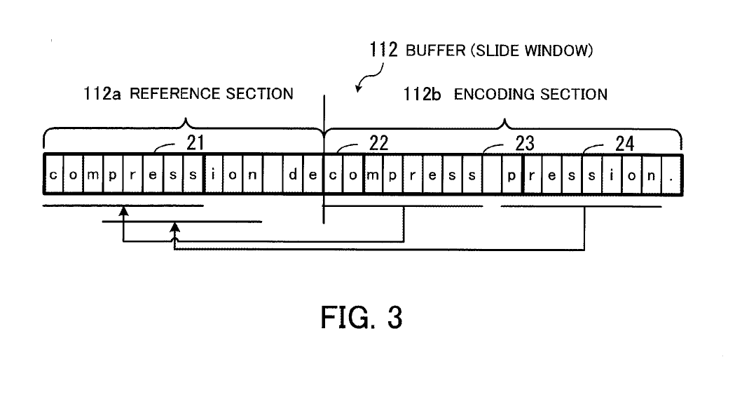

FIG. 3 illustrates association between the dictionary and symbols. In the second embodiment, a buffer 112 called a “slide window” is provided. Encoding target symbol strings are sequentially stored in the buffer 112 from the beginning thereof by the first-in, first-out (FIFO) method. The first half of the buffer 112 is a reference section 112a and the second half is an encoding section 112b. Encoded symbol strings are stored in the reference section 112a. Uncoded symbol strings are stored in the encoding section 112b.

In the second embodiment, encoding target data is divided into a plurality of blocks 21 through 24. Each of the blocks 21 through 24 includes a predetermined number of symbol strings. In the example of FIG. 3, each symbol has a data length of 1 byte, and each block includes 8 symbols. That is, each block includes 8 bytes.

Upon encoding uncoded symbols, the longest matching symbol string that matches a symbol string starting at the beginning of the encoding section 112b is searched for, in the reference section 112a. In the example of FIG. 3, a symbol string “compress pression.” is stored in the encoding section 112b. A symbol string that matches a symbol string “compress” included in this symbol string is detected in the reference section 112a. Then, the symbol string “compress” is encoded into a code indicating the position of the matching symbol string in the reference section 112a and the match end position of the symbol string in the encoding section 112b.

As for the symbol string following “compress”, a symbol that matches only the space symbol at the beginning of the symbol string is detected in the reference section 112a. In the case where the matching symbol string includes only one symbol, even if encoding is performed, there would not be a great effect of reducing the amount of data. Therefore, in the second embodiment, in the case where a matching symbol string includes only one symbol, a determination is made that a matching symbol string is not present. Note that the minimum length for a symbol string to be determined as a match may be arbitrarily set. For example, when a symbol string has one matching symbol (one matching byte), the symbol string may be determined as a match. Further, for example, when a symbol string has at least three matching symbols (three matching bytes), the symbol string may be determined as a match. A symbol string (non-matching symbol string) for which a matching symbol string is not found is encoded to a code (no-match code) indicating that a matching symbol string is not present in the reference section 112a and a code indicating the position of the corresponding symbol string in the compressed data and the no-match end position of the non-matching symbol string.

A symbol string that matches the symbol string “pression” after the space is detected in the reference section 112a. Then, the symbol string “pression” is encoded into a code indicating the position of the matching symbol string in the reference section 112a and the match end position of the symbol string in the encoding section 112b.

In the second embodiment, when compressing data, a symbol string is encoded into a code such that memory access is easily performed in units of blocks upon decompression of the data.

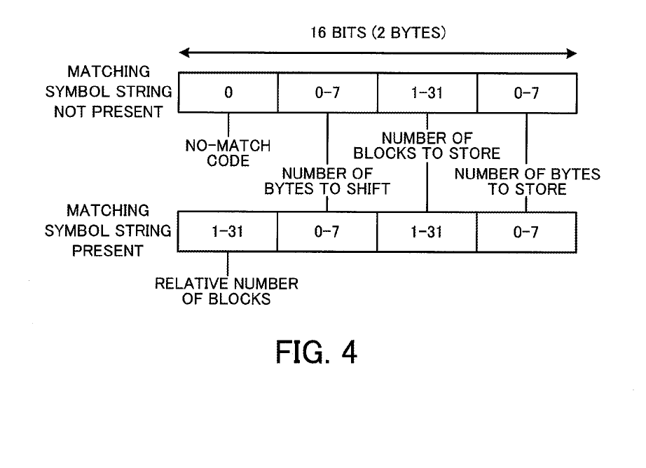

FIG. 4 illustrates exemplary data structures of codes. In the second embodiment, a symbol string is encoded to a 2-byte (16-bit) code. A symbol string for which a matching symbol string is found is encoded into values indicating the relative number of blocks, the number of bytes to shift, the number of blocks to store, and the number of bytes to store. On the other hand, a symbol string for which a matching symbol is not found is encoded into values indicating a no-match code, the number of bytes to shift, the number of blocks to store, and the number of bytes to store. The relative number of blocks is 5-bit data that takes a value in the range from 1 through 31. The number of bytes to shift is 3-bit data that takes a value in the range of 0 through 7. The number of blocks to store is 5-bit data that takes a value in the range of 1 through 31. The number of bytes to store is 3-bit data that takes a value in the range of 0 through 7. In the case where a matching symbol string is not present, “0” is set in the field of the relative number of blocks. The value “0” represents a no-match code.

Next, the meaning of each value of the code will be described.

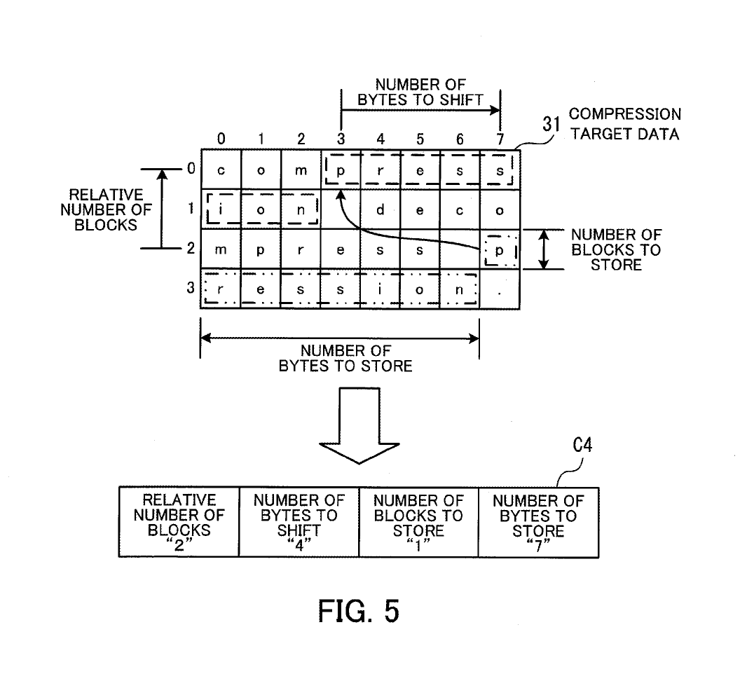

FIG. 5 illustrates an example of a code for the case where a matching symbol string is present. Compression target data 31 is divided into blocks of 8 bytes each. Each block is assigned an address in ascending order starting with “0”. Each symbol (1 byte) in the block is assigned a byte number in ascending order starting with “0”, sequentially from the left.

In the following, encoding of a symbol string “pression” will be described. The encoding target symbol string “pression” has 8 bytes (from the eighth symbol (the byte number in the block: “7”) of the block at the block address “2” to the seventh symbol (the byte number in the block: “6”) of the block at the block address “3”). The symbol string that matches the encoding target symbol string has 8 bytes (from the fourth symbol (the byte number in the block: “3”) of the block at the block address “0” to the third symbol (the byte number in the block: “2”) of the block at the block address “1”.

The relative number of blocks is the difference between the address of the block containing the beginning of the encoding target symbol string and the address of the block containing the beginning of the matching symbol string. In the example of FIG. 5, the relative number of blocks is “2”.

The number of bytes to shift is the difference between the position of the beginning of the encoding target symbol string in its block and the position of the beginning of the matching symbol string in its block. For example, the number of bytes to shift is the value obtained by subtracting the byte number indicating the position of the beginning of the matching symbol string in its block from the byte number indicating the position of the beginning of the encoding target symbol in its block. If the value obtained by the subtraction is negative, “8” (the number of bytes in one block) is added to the subtraction result. In the example of FIG. 5, the number of bytes to shift is “4”.

The number of blocks to store is the difference between the address of the block containing the beginning of the encoding target symbol string and the address of the block containing the last symbol (match end position) of the encoding target symbol string. In the example of FIG. 5, the number of blocks to store is “1”.

The number of bytes to store is the number of symbols from the beginning of the block containing the last symbol of the encoding target symbol string to the last symbol of the encoding target symbol string. In the example of FIG. 5, the number of bytes to store is “7”.

In this way, a code C4 for the case where a matching symbol string is present is generated. Next, a code for the case where a matching symbol string is not present will be described. Note that if there is a sequence of symbols for which a matching symbol string is not found, a string of these symbols is encoded all at once.

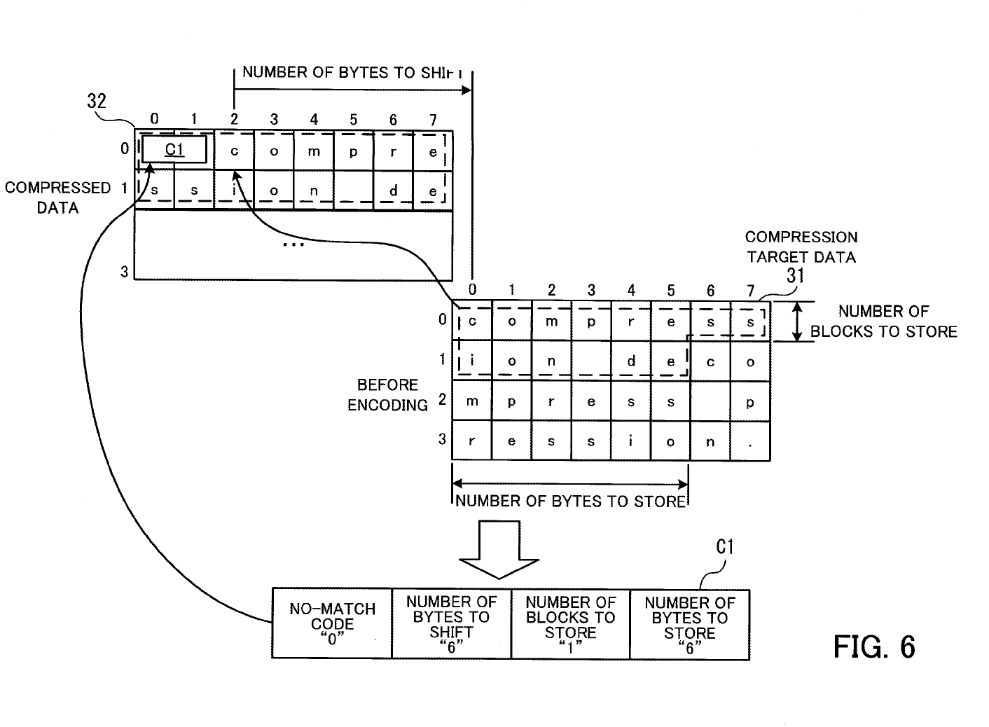

FIG. 6 illustrates an example of a code for the case where a matching symbol string is not present. In the case where a matching symbol string is not present, a code is generated on the basis of information on the position of a symbol in compressed data 32. The compressed data 32 is divided into blocks of 8 bytes each. Each block is assigned an address in ascending order starting with “0”. Each symbol (1 byte) in the block is assigned a byte number in ascending order starting with “0”, sequentially from the left.

In the following, encoding of a symbol string “compression de” will be described. This symbol string has 14 bytes (from the first symbol (the byte number in the block: “0”) of the block at the block address “0” to the sixth symbol (the byte number in the block: “5”) of the block at the block address “1”). A symbol string that matches this symbol string is not found. Accordingly, the first 5 bits of the code are set to “0” representing a no-match code.

The number of bytes to shift is the difference between the position of the beginning of the encoding target symbol string in its block and the position of a beginning of a corresponding symbol string stored in the compressed data 32 in its block. For example, the number of bytes to shift is the value obtained by subtracting the byte number indicating the position of the beginning of the corresponding symbol string in its block in the compressed data 32 from the byte number indicating the position of the beginning of the encoding target symbol in its block. If the value obtained by the subtraction is negative, “8” (the number of bytes in one block) is added to the subtraction result. In the case where a matching symbol string is not present, the compression target symbol string is stored after the generated code (2 bytes). Accordingly, the position of the beginning of the symbol string in the compressed data 32 is determined in consideration of the code. In the example of FIG. 6, the byte number indicating the position of the beginning of the encoding target symbol in its block is “0”, and the byte number indicating the position of the beginning of the corresponding symbol string in its block in the compressed data 32 is “2”. Then, “−2” is obtained by subtracting “2” from “0”. Since the subtraction result is negative, 8 is added. Thus, the number of bytes to shift is “6”.

The number of blocks to store is the difference between the address of the block containing the beginning of the encoding target symbol string and the address of the block containing the last symbol (no-match end position) of the encoding target symbol string. In the example of FIG. 6, the number of blocks to store is “1”.

The number of bytes to store is the number of symbols from the beginning of the block containing the last symbol of the encoding target symbol string to the last symbol of the encoding target symbol string. In the example of FIG. 6, the number of bytes to store is “6”.

A generated code C1 is stored in a storage area of the compressed data 32. Then, an uncoded non-matching symbol string is stored after the code C1. In the example of FIG. 6, a symbol string “compression de” is stored after the code C1.

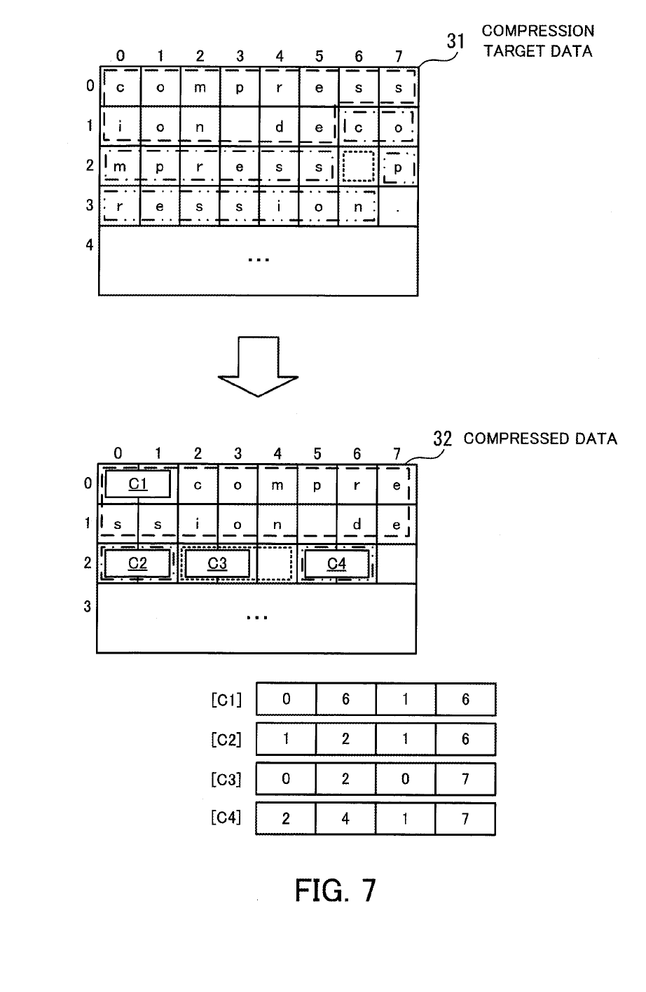

FIG. 7 illustrates an example of compressed data. In the example of FIG. 7, the symbol string “compression de” is stored after the code C1 in the compressed data 32. The symbol string “compress” is compressed into a code C2, and the code C2 is stored in the compressed data 32. The space symbol is stored after a code C3 in the compressed data 32. The symbol string “pression” is compressed into the code C4, and the code C4 is stored in the compressed data 32.

Since data is encoded in the manner illustrated in FIGS. 3 through 7, the data amount of the compressed data is reduced compared to the original data. That is, the data is compressed. This compression scheme is a lossless compression scheme. Accordingly, the data may be decompressed from the compressed data without any data loss.

Next, a description will be given of functions of the computer 100 for compressing data by using the encoding technique illustrated in FIGS. 3 through 7 and decompressing the compressed data.

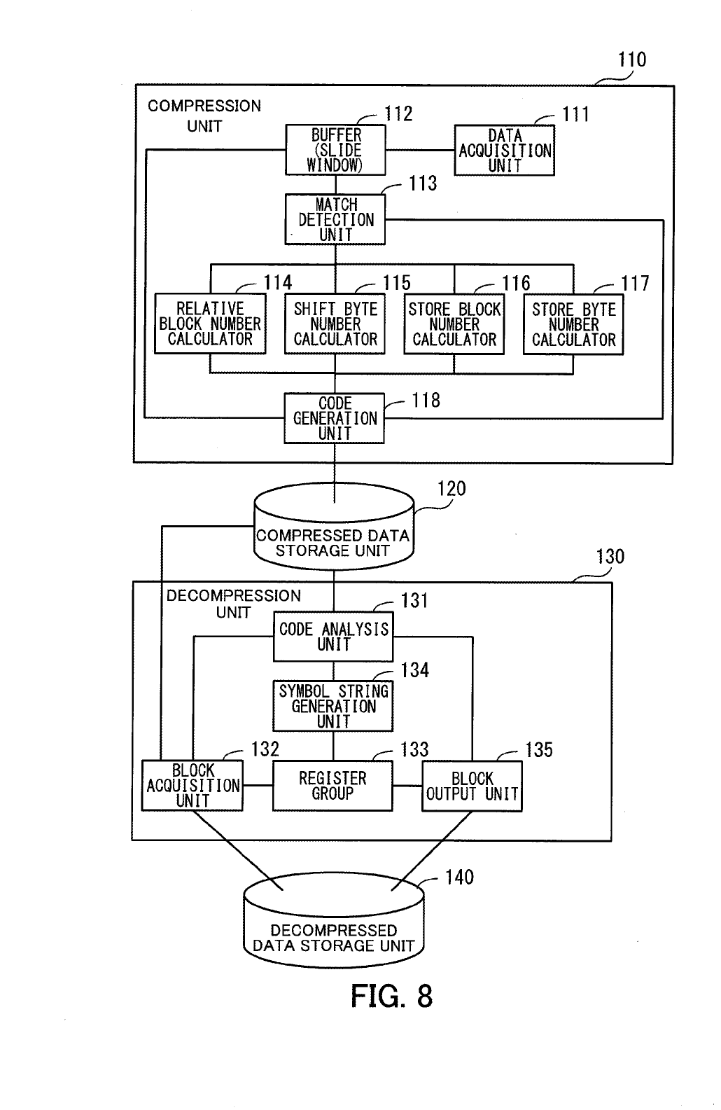

FIG. 8 is a block diagram illustrating functions for compressing and decompressing data. The computer 100 includes a compression unit 110, a compressed data storage unit 120, a decompression unit 130, and a decompressed data storage unit 140.

The compression unit 110 compresses compression target data. For example, the compression unit 110 compresses data stored in any of the RAM 102, the HDD 103, the optical disc 14, and the memory card 17. Further, the compression unit 110 may compress data received via the network 10. The compression unit 110 stores the compressed data in the compressed data storage unit 120.

The compressed data storage unit 120 stores the compressed data that is compressed by the compression unit 110. For example, a part of the storage area of any of the RAM 102, the HDD 103, the optical disc 14, and the memory card 17 may be used as the compressed data storage unit 120.

The decompression unit 130 decompresses compressed data stored in the compressed data storage unit 120 to the original data. The decompression unit 130 writes the decompressed data to the decompressed data storage unit 140 in units of blocks. Further, when decompressing data, the decompression unit 130 reads blocks of already decompressed symbols from the decompressed data storage unit 140 in units of blocks, or reads symbols in the compressed data from the compressed data storage unit 120 in units of blocks. Then, the decompression unit 130 replaces a code in the compressed data with the symbols in the read block, and thereby decompresses the code to the original symbols.

The decompressed data storage unit 140 stores the decompressed data. For example, a part of the storage area of any of the RAM 102, the HDD 103, the optical disc 14, and the memory card 17 may be used as the decompressed data storage unit 140. In order to perform decompression at high speed, a device that allows high-speed access is preferably used as the decompressed data storage unit 140. Therefore, in the second embodiment, a part of the RAM 102 is used as the decompressed data storage unit 140.

Next, the functions of the compression unit 110 and the decompression unit 130 will be described in greater detail.

The compression unit 110 includes a data acquisition unit 111, the buffer 112, a match detection unit 113, a relative block number calculator 114, a shift byte number calculator 115, a store block number calculator 116, a store byte number calculator 117, and a code generation unit 118.

The data acquisition unit 111 acquires compression target data. For example, the data acquisition unit 111 identifies compression target data on the basis of an input from the user. The compression target data may be data stored in the HDD 103, the optical disc 14, or the memory card 17, for example. The compression target data may be data received by the network interface 108 via the network 10. The data acquisition unit 111 sequentially stores the compression target data (symbol string) in the buffer 112.

The buffer 112 stores a predetermined amount of encoded symbol strings and a predetermined amount of encoding target symbol strings. The configuration of the buffer 112 is illustrated in FIG. 3.

The match detection unit 113 detects the longest symbol string that matches a symbol string starting at the beginning of the encoding section 112b, from the symbol string in the reference section 112a of the buffer 112. If a matching symbol string is found, the match detection unit 113 identifies the position of the matching symbol string in the reference section 112a and the length of the symbol string. On the other hand, if a matching symbol string is not found, the match detection unit 113 identifies the length of the non-matching symbol string. Then, if a matching symbol string is not found, the match detection unit 113 outputs a 5-bit value of “0” representing a no-match code to the code generation unit 118. Alternatively, if a matching symbol string is not found, the match detection unit 113 may output information indicating no match to the code generation unit 118. Upon reception of the information indicating no match, the code generation unit 118 generates a code. In this step, the code generation unit 118 sets the first 5 bits of the code to “0”.

The relative block number calculator 114 calculates the relative number of blocks if a matching symbol string is found by the match detection unit 113. For example, the relative block number calculator 114 subtracts the address of the block containing the matching symbol string in the reference section 112a from the address of the block containing the beginning of the encoding section 112b. Then, the relative block number calculator 114 sets the result of the subtraction as the relative number of blocks. Then, the relative block number calculator 114 outputs the relative number of blocks represented by 5 bits to the code generation unit 118.

The shift byte number calculator 115 calculates the number of bytes to shift, in accordance with the detection result of the match detection unit 113. For example, if a matching symbol string is found, the shift byte number calculator 115 adds 8 to the byte number of the beginning of the encoding section 112b. By adding 8, the result of the following subtraction always becomes a positive value. The shift byte number calculator 115 subtracts the byte number of the beginning of the matching symbol string in the reference section 112a from the addition result. Then, the shift byte number calculator 115 sets the remainder after dividing the subtraction result by 8 as the number of bytes to shift. On the other hand, if a matching symbol string is not found, the shift byte number calculator 115 adds 8 to the byte number of the beginning of the encoding section 112b, and then subtracts the byte number of the beginning of the corresponding symbol string in the compressed data. Then, the shift byte number calculator 115 sets the remainder after dividing the subtraction result by 8 as the number of bytes to shift. The shift byte number calculator 115 outputs a 3-bit value representing the calculated number of bytes to shift to the code generation unit 118.

The store block number calculator 116 calculates the number of blocks to store, in accordance with the detection result of the match detection unit 113. For example, if a matching symbol string is found, the store block number calculator 116 subtracts the address of the block containing the beginning of the encoding section 112b from the address of the block containing the last symbol (match end position) of the matching symbol string in the encoding section 112b. Then, the store block number calculator 116 sets the result of the subtraction as the number of blocks to store. On the other hand, if a matching symbol string is not found, the store block number calculator 116 subtracts the address of the block containing the beginning of the encoding section 112b from the address of the block containing the last symbol of the non-matching symbol string. The store block number calculator 116 sets the result of the subtraction as the number of blocks to store. The store block number calculator 116 outputs a 5-bit value representing the calculated number of blocks to store to the code generation unit 118.

The store byte number calculator 117 calculates the number of bytes to store, in accordance with the detection result of the match detection unit 113. For example, if a matching symbol string is found, the store byte number calculator 117 sets, as the number of bytes to store, the number of symbols from the beginning of the block containing the last symbol of the symbol string in the encoding section 112b for which the matching symbol string is found to the last symbol of the symbol string. Note that this number of symbols is a value obtained by adding 1 to the byte number of the last symbol of the encoding target symbol string. On the other hand, if a matching symbol string is not found, the store byte number calculator 117 sets, as the number of bytes to store, the number of symbols from the beginning of the block containing the last symbol of the non-matching symbol string to the last symbol of the non-matching symbol string. Then, the store byte number calculator 117 outputs a 3-bit value representing the calculated number of bytes to store to the code generation unit 118.

The code generation unit 118 sets the output value of the relative block number calculator 114, the output value of the shift byte number calculator 115, the output value of the store block number calculator 116, and the output value of the store byte number calculator 117 in a 2-byte field in this order. The code generation unit 118 stores the obtained 2-byte value as a code in the compressed data storage unit 120. If a no-match code is output from the relative block number calculator 114, the code generation unit 118 acquires a non-matching symbol string from the encoding section 112b of the buffer 112. Then, the code generation unit 118 stores, in the compressed data storage unit 120, the acquired non-matching symbol string after a code for the case where a matching symbol string is not found.

Note that the search unit 2a of FIG. 1 is realized by the data acquisition unit 111, the buffer 112, and the match detection unit 113 of the compression unit 110. The encoding unit 2b of FIG. 1 is realized by the relative block number calculator 114, the shift byte number calculator 115, the store block number calculator 116, the store byte number calculator 117, and the code generation unit 118.

Next, functions of the decompression unit 130 will be described in greater detail.

The decompression unit 130 includes a code analysis unit 131, a block acquisition unit 132, a register group 133, a symbol string generation unit 134, and a block output unit 135.

The code analysis unit 131 acquires compressed data to be decompressed, from the compressed data storage unit 120. Then, the code analysis unit 131 sequentially analyzes codes of the acquired compressed data from the beginning thereof. For example, the code analysis unit 131 acquires 2 bytes of the code at a time from the beginning of the compressed data. The code analysis unit 131 recognizes the beginning 5 bits of the acquired code as a relative number of blocks, the next 3 bits as the number of bytes to shift, the next 5 bits as the number of blocks to store, and the last 3 bits as the number of bytes to store. However, if the value of the beginning 5 bits is 0, the code analysis unit 131 recognizes these 5 bits not as the relative number of blocks but as a no-match code.

The block acquisition unit 132 acquires blocks to be used for decompression of the data from the compressed data storage unit 120 or the decompressed data storage unit 140, on the basis of the results of the analysis by the code analysis unit 131. For example, if the relative number of blocks is contained in a code to be decompressed, the block acquisition unit 132 sequentially acquires blocks starting at the address preceding the block being decompressed (the current block) by the relative number of blocks, from the decompressed data storage unit 140. If a no-match code is contained in the code to be decompressed, the block acquisition unit 132 acquires a symbol string stored after the code to be decompressed, from the compressed data storage unit 120 in units of blocks. The block acquisition unit 132 continues acquisition of blocks corresponding to a code to be decompressed until the same number of blocks as the number of blocks to store, which is indicated by the code, are stored.

The register group 133 includes a plurality of registers that store the values (symbol string) of blocks acquired by the block acquisition unit 132. Operations such as shifting and merging symbol strings and the like are performed in the register group 133, so that symbol strings before compression may be decompressed.

The symbol string generation unit 134 manipulates symbol strings in the register group 133 on the basis of the results of the analysis by the code analysis unit 131, and decompresses the symbol string before compression in units of blocks.

The block output unit 135 stores the decompressed symbol string, which is decompressed in the register group 133, in the decompressed data storage unit 140 in units of blocks.

Note that the code acquisition unit 4a of FIG. 1 is realized by the code analysis unit 131. The decompression unit 4b of FIG. 1 is realized by the block acquisition unit 132, the register group 133, the symbol string generation unit 134, and the block output unit 135.

The lines connecting the components of FIG. 8 represent some of communication paths. Communication paths other than those of FIG. 8 may be provided.

Next, the procedure of a compression process will be described.

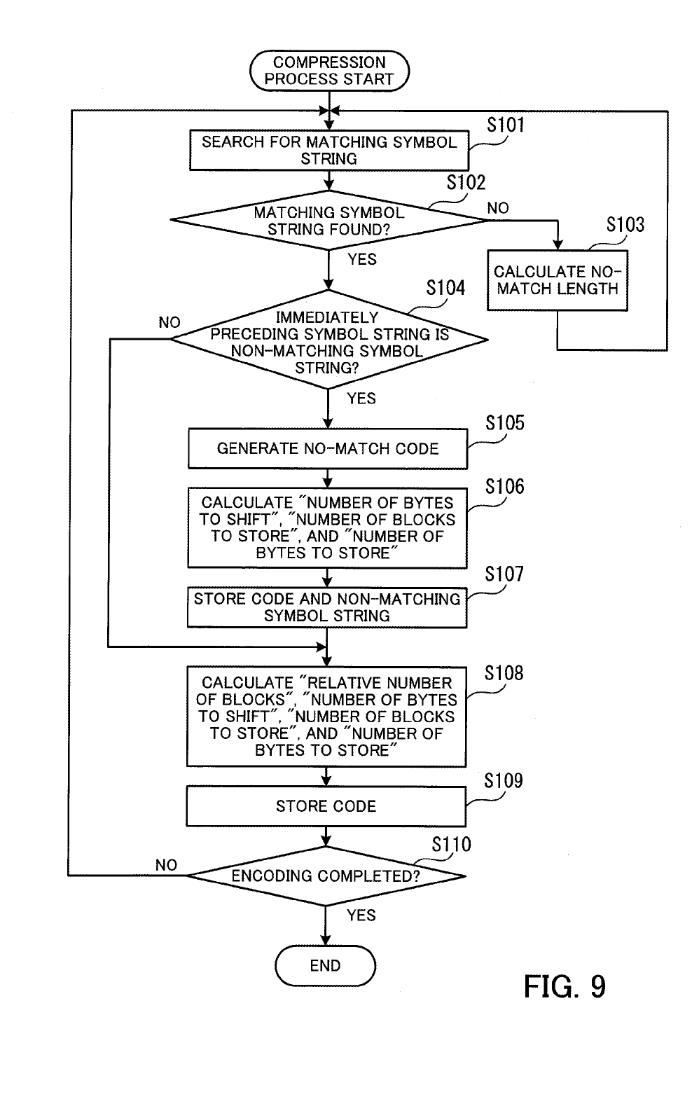

FIG. 9 is a flowchart illustrating an exemplary procedure of a compression process. This process is performed when a compression instruction specifying compression target data is input, for example.

(Step S101) The data acquisition unit 111 stores, in the encoding section 112b, an amount of symbol strings corresponding to the capacity of the encoding section 112b of the buffer 112 sequentially from the beginning of compression target data. Note that symbols encoded in the encoding section 112b are shifted to the reference section 112a. Accordingly, each time a symbol string is encoded, the data acquisition unit 111 stores an amount of uncompressed symbol strings corresponding to the amount of the encoded data in the encoding section 112b.

Then, the match detection unit 113 sequentially selects symbols from the beginning of the encoding section 112b of the buffer 112, and searches for a symbol string that matches the selected symbol string from the reference section 112a.

(Step S102) The match detection unit 113 determines whether a matching symbol string is present. If a matching symbol string is present, the process proceeds to step S104. If a matching symbol string is not present, the process proceeds to step S103.

(Step S103) If a matching symbol string is not found, the match detection unit 113 calculates the length (the number of bytes) of the symbols for which matching symbols are not found. For example, the number of bytes of the symbols for which matching symbols are not found by a new search is added to the length of symbols for which matching symbols are not found by the previous search. Then, the process returns to step S101, in which the match detection unit 113 selects the next symbol and searches for a matching symbol string.

(Step S104) If a matching symbol is found, the match detection unit 113 determines whether a symbol string (non-matching symbol string) for which a matching symbol is not found is present immediately before the symbol string for which a matching symbol is found. If a non-matching symbol string is present, the process proceeds to step S105. If a non-matching symbol string is not present, the process proceeds to step S108.

(Step S105) If a non-matching symbol string is present, the match detection unit 113 generates a no-match code. The match detection unit 113 outputs the no-match code to the code generation unit 118.

(Step S106) The shift byte number calculator 115, the store block number calculator 116, and the store byte number calculator 117 calculate the number of bytes to shift, the number of blocks to store, and the number of bytes to store, respectively. Note that the number of blocks to store and the number of bytes to store are calculated using the length for which matching symbols are not found. That is, the length from the beginning of the encoding section 112b for which matching symbols are not found is the length of the non-matching symbol string. The position of the last symbol of the non-matching symbol string is the no-match end position. The number of blocks to store and the number of bytes to store are calculated on the basis of the no-match end position. The shift byte number calculator 115, the store block number calculator 116, and the store byte number calculator 117 output the respective calculated values to the code generation unit 118.

(Step S107) The code generation unit 118 connects the output values so as to generate a code for the case where a matching symbol string is not present. Then, the code generation unit 118 stores the generated code in the compressed data storage unit 120. Then, the code generation unit 118 acquires the non-matching symbol string from the encoding section 112b of the buffer 112, and stores the symbol string in the compressed data storage unit 120.

(Step S108) The relative block number calculator 114, the shift byte number calculator 115, the store block number calculator 116, and the store byte number calculator 117 calculate the relative number of blocks, the number of bytes to shift, the number of blocks to store, and the number of bytes to store, respectively. The relative block number calculator 114, the shift byte number calculator 115, the store block number calculator 116, and the store byte number calculator 117 output the respective calculated values to the code generation unit 118.

(Step S109) The code generation unit 118 connects the output values so as to generate a code for the case where a matching symbol string is present. Then, the code generation unit 118 stores the generated code in the compressed data storage unit 120.

(Step S110) The match detection unit 113 determines whether encoding of the entire data is completed. For example, the match detection unit 113 determines that the encoding is completed, when the encoding section 112b of the buffer 112 becomes empty. If the encoding is completed, the data compression process ends. If the encoding is not completed, the process returns to step S101.

In this way, the data is compressed, and the compressed data 32 is stored in the compressed data storage unit 120. The decompression unit 130 decompresses the compressed data 32 stored in the compressed data storage unit 120 to the original data.

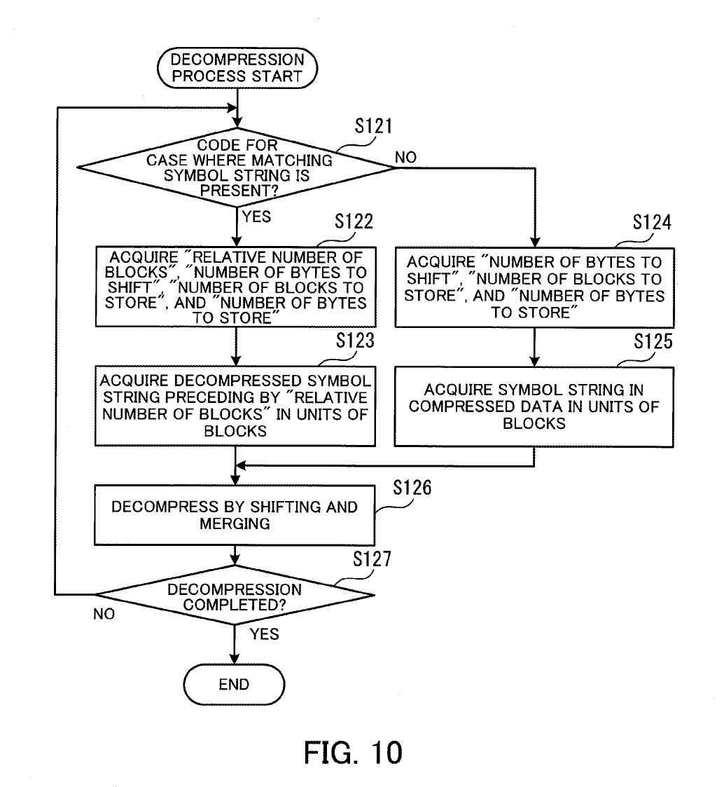

FIG. 10 is a flowchart illustrating an exemplary procedure of a data decompression process. This process is performed when a decompression instruction specifying compressed data is input, for example.

(Step S121) The code analysis unit 131 sequentially reads codes from the beginning of compressed data. Then, the code analysis unit 131 determines whether the read code is a code for the case where a matching symbol string is present. For example, if the value of the beginning 5 bits of the code is not “0”, the code is for the case where a matching symbol string is present. If the code is for the case where a matching symbol string is present, the process proceeds to step S122. If the code is for the case where a matching symbol string is not present, the process proceeds to step S124.

(Step S122) If the code is for the case where a matching symbol string is present, the code analysis unit 131 acquires the relative number of blocks, the number of bytes to shift, the number of blocks to store, and the number of bytes to store, from the acquired code.

(Step S123) The block acquisition unit 132 acquires, from the decompressed data storage unit 140, the decompressed block preceding the block containing the storage position (current position) of the next decompressed symbol by the relative number of blocks. The block acquisition unit 132 stores the acquired block in the register group 133. Then, the process proceeds to step S126.

(Step S124) If the code is for the case where a matching symbol string is not present, the code analysis unit 131 acquires the number of bytes to shift, the number of blocks to store, and the number of bytes to store, from the acquired code.

(Step S125) The block acquisition unit 132 acquires a symbol string stored after the acquired code in the compressed data storage unit 120 in units of blocks. The block acquisition unit 132 stores the acquired blocks in the register group 133.

(Step S126) The symbol string generation unit 134 performs shifting and merging of symbol strings in the register group 133, and thereby decompresses a symbol string corresponding to the code. Then, the block output unit 135 stores the decompressed symbol string in the decompressed data storage unit 140 in units of blocks.

(Step S127) The code analysis unit 131 determines whether decompression of the compressed data is completed. If the decompression is completed, the process ends. If the decompression is not completed, the process returns to step S121.

In this way, the original data may be decompressed from compressed data. Note that, in the second embodiment, a symbol string may be decompressed by performing shifting and merging of symbol strings in the register group 133.

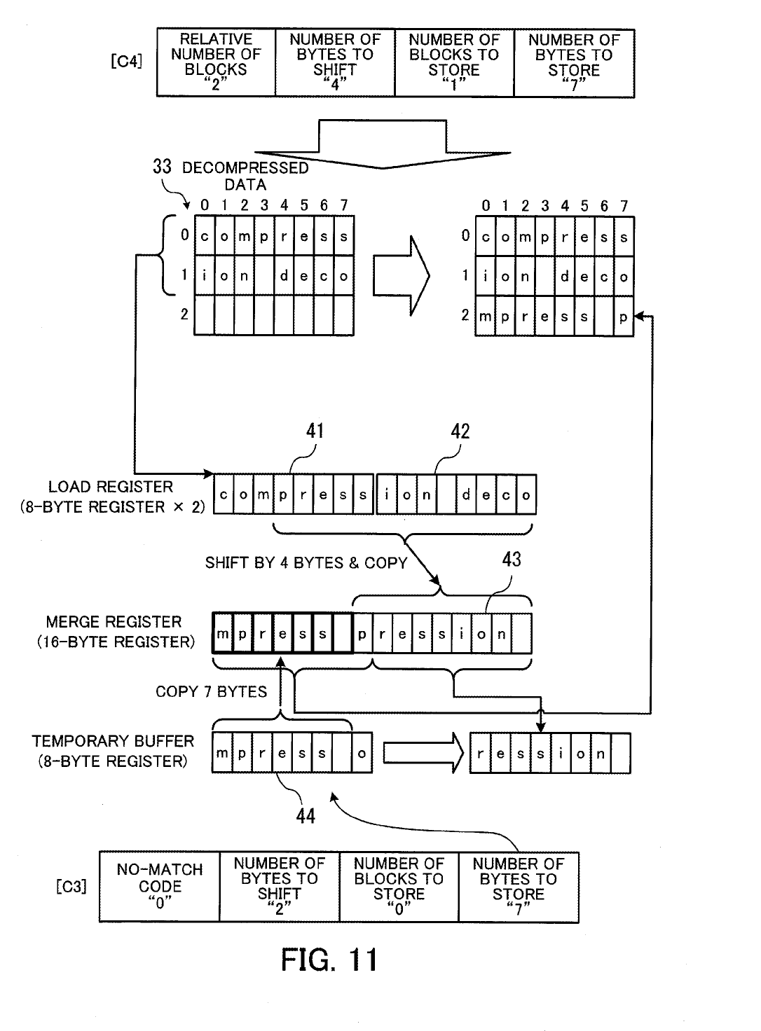

FIG. 11 illustrates a decompression procedure using the register group 133. In the example of FIG. 11, the registers of the register group 133 are used for three purposes.

Load registers 41 and 42 store a symbol string which is acquired by the block acquisition unit 132 in units of blocks. For example, two 8-byte registers are used as the load registers 41 and 42.

A merge register 43 is a register used for merging symbol strings. For example, a 16-byte register is used as the merge register 43.

A temporary buffer 44 is a buffer that stores a symbol string contained in the decompressed symbol string that is yet to be stored in the decompressed data storage unit 140. For example, an 8-byte register is used as the temporary buffer 44.

Now, a description will be given of a decompression procedure in the case of decompressing the code C4 to a symbol string on the basis of the decompressed data. When decompressing the code C4, the codes preceding the code C4 in the compressed data 32 are already decompressed, and are stored in the storage area of decompressed data 33 in units of blocks. A symbol string decompressed by the previous decompression is stored in the temporary buffer 44. In the symbol string in the temporary buffer 44, a symbol string having the number of bytes indicated by the number of bytes to store “7” of an immediately preceding code C3 is the decompressed symbol string. In the example of FIG. 11, a symbol string “mpress” is the decompressed symbol string.

In the case of decompressing data on the basis of the code C4, a string is first acquired in units of blocks on the basis of the relative number of blocks of the code C4. For example, the relative number of blocks of the code C4 is “2”. Accordingly, the block at the second preceding address “0” to the address “2” of the current block is acquired. In the example of FIG. 11, two blocks are acquired so as to decompress the code C4. The acquired blocks are stored in the load registers 41 and 42. Note that a plurality of blocks do not have to be stored in the load registers 41 and 42 at the same time. For example, the block at the address “0” in FIG. 11 is stored in the load register 41, and then operations of shifting and merging symbol strings and an operation of storing a decompressed block may be performed. In the case of the number of decompressed blocks is less than the number of blocks to store, the next block is written to the load register 41.

Then, the symbol string in the load registers 41 and 42 and the symbol string in the temporary buffer 44 are merged in the merge register 43. In this step, a symbol string of the number of bytes to store (7 bytes) indicated by the immediately preceding code C3, starting at the beginning of the temporary buffer 44, is copied to the beginning of the merge register 43. Then, the symbol string in the load registers 41 and 42 are shifted to the right by the number of bytes to shift “4” of the code C4, and is copied to the area of the temporary buffer 44 where no symbol string is stored. For example, the symbol “p” of the fourth byte of the load register 41 is shifted by 4 bytes, and thus is stored in the eighth byte of the merge register 43. The symbol string “com” of the first 3 bytes of the load register 41 is not copied because the position of the symbol string “com” shifted by 4 bytes overlaps the area in which the symbol string of the temporary buffer 44 to be copied is stored.

When the merging of symbol strings is completed, the decompressed block is added to the decompressed data 33. In the example of FIG. 11, the number of blocks to store of the code C4 is “1”. Accordingly, when the merging is completed, the block at the beginning of the merge register 43 is added to the decompressed data 33. In the symbol string decompressed in the merge register 43, a symbol string of less than one block is stored in the temporary buffer 44. The number of bytes to store of the code C4 is “7”. That is, in the symbol string stored in the temporary buffer 44, a symbol string of the beginning 7 bytes is a decompressed symbol string.

In this way, it is possible to acquire a symbol string in units of blocks, and decompress data in units of blocks by performing simple operations in the register group 133, and store the decompressed data.

Next, a description will be given of a detailed procedure of compression and decompression including manipulations of symbol strings in the register.

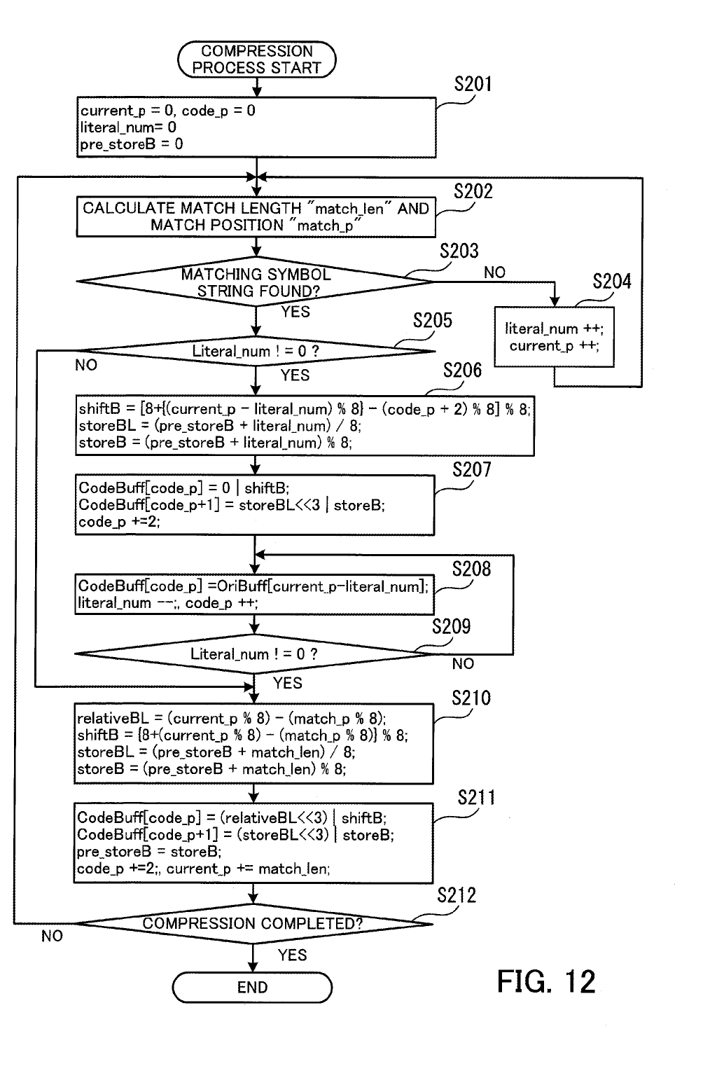

FIG. 12 is a flowchart illustrating an exemplary procedure of a compression process using registers efficiently.

(Step S201) The data acquisition unit 111 stores compression target data in the buffer 112, and the match detection unit 113 initializes parameters. The parameters to be initialized are as follows.

current_p=0
code_p=0
literal_num=0
pre_storeB=0

The “current_p” indicates the byte order of the position of a symbol in the compression target data 31 for which a matching symbol is being searched for. The “code_p” indicates the byte order of the storage position of a generated code in the compressed data 32. The “literal_num” indicates the length of a non-matching symbol string. The “pre_storeB” indicates the number of bytes of a symbol string (the present number of bytes to store) stored in the temporary buffer 44 as a result of decompression of the immediately preceding code.

(Step S202) The match detection unit 113 searches for a symbol string that matches a symbol string starting with a symbol indicated by the “current_p”, from the reference section 112a. If a matching symbol string is found, the match detection unit 113 sets the length of the matching symbol string as the “match_len”, and sets the beginning position of the matching symbol string in the reference section 112a as the “match_p”.

(Step S203) The match detection unit 113 determines whether a matching symbol string is found by the search of step S202. If a matching symbol string is found, the process proceeds to step S205. If a matching symbol string is not found, the process proceeds to step S204.

(Step S204) The match detection unit 113 increments (adds 1 to) the value of the “literal_num”. Further, the match detection unit 113 increments the value of the “current_p”. Then, the process returns to step S202.

(Step S205) The match detection unit 113 determines whether the value of the “literal_num” is 0. If the value of the “literal_num” is not 0, a non-matching symbol string is present. Then, the process proceeds to step S206. If the value of the “literal_num” is 0, a non-matching symbol string is not present. Then, the process proceeds to step S210.

(Step S206) The shift byte number calculator 115, the store block number calculator 116, and the store byte number calculator 117 calculate the number of bytes to shift, the number of blocks to store, and the number of bytes to store, respectively.

The number of bytes to shift “shiftB” is calculated by, for example, the following expression.

shiftB=[8+{(current_{—}p−literal_num)%8}−(code_{—}p+2)%8]%8 (1)

The “=” is the assignment operator. The “%” is the remainder operator. The “current_p−literal_num” indicates the position of the beginning of the non-matching symbol string. The remainder after dividing the “current_p−literal_num” by 8 indicates the position of the beginning of the non-matching symbol string in the block in the compression target data 31. The “(code_p+2)” indicates the next position of the code (2 bytes) for the case of no match in the compressed data 32. This position is the position of the non-matching symbol string in the compressed data 32. The remainder after dividing the “current_p+2” by 8 indicates the position of the beginning of the non-matching symbol string in the block in the compressed data 32. The expression (1) sets, as the number of bytes to shift “shiftB”, the difference between the position of the beginning of the non-matching symbol string in the block of the compression target data 31 and the position of the beginning of the non-matching symbol string in the block in the compressed data 32.

The number of blocks to store “storeBL” is calculated by, for example, the following expression.

storeBL=(pre_storeB+literal_num)/8 (2)

The “/” is the division operator that returns the quotient of the division.

The number of bytes to store “storeB” is calculated by, for example, the following expression.

storeB=(pre_storeB+literal_num)%8 (3)

(Step S207) The code generation unit 118 generates a code on the basis of the values calculated in step S206. For example, the code generation unit 118 performs the following operations.

CodeBuff[code_{—}p]=0|shiftB (4)

CodeBuff[code_{—}p+1]=storeBL<<3|storeB (5)

The “|” is the bitwise OR operator. The “<<” is an operator for shifting to the left by the number of bytes specified by the value on the right side. The “CodeBuff[ ]” indicates the buffer (the compressed data storage unit 120) that stores the compressed data 32. For example, the “CodeBuff[code_p]” indicates the storage area specified by the “code_p” in the compressed data 32. The expression (4) sets, in the compressed data 32, a 1-byte value (the first half of the code) indicating the no-match code and the number of bytes to shift. After the value set by the expression (4), a 1-byte value (the second half of the code) indicating the number of blocks to store and the number of bytes to store is set by the expression (5). Then, the next storage position in the compressed data 32 is advanced by 2 bytes. That is, the “code_p+=2” is executed. The “+=” represents adding the value on the right side to the parameter on the left side.

(Step S208) The code generation unit 118 copies one symbol of the non-matching symbol string to the compressed data 32. For example, copying is performed by the following instruction.

CodeBuff[code_{—}p]=OriBuff[current_{—}p−literal_num] (6)

The “OriBuff[ ]” indicates the buffer storing the compression target data 31. The value in “[ ]” specifies the storage area in the buffer. The expression (6) copies, to the compressed data 32, the symbols of the non-matching symbol string that are not yet copied. Then, the “literal_num” is decremented (literal_num −−). Further, the “code_p” is incremented, so that the next storage position in the compressed data 32 is advanced by 1 byte (code_p++).

(Step S209) The code generation unit 118 determines whether copying of the entire non-matching symbol string is completed. For example, the code generation unit 118 determines whether copying of the non-matching symbol string is completed on the basis of whether the “literal_num” is “0”. If the copying of the non-matching symbol string is completed, the process proceeds to step S210. If the copying of the non-matching symbol string is not completed, the process returns to step S208.

(Step S210) The relative block number calculator 114, the shift byte number calculator 115, the store block number calculator 116, and the store byte number calculator 117 calculate the relative number of blocks, the number of bytes to shift, the number of blocks to store, and the number of bytes to store, respectively.

The relative number of blocks “relativeBL” is calculated by, for example, the following expression.

relativeBL=(current_{—}p%8)−(match_{—}p%8) (7)

The “(current_p %8)” calculates the address of the block containing the beginning of the matching symbol string in the encoding section 112b. The “(match_p %8)” calculates the address of the block containing the beginning of the matching symbol string in the reference section 112a. The expression (7) calculates the difference between these addresses.

The number of bytes to shift “shiftB” is calculated by, for example, the following expression.

shiftB={8+(current_{—}p%8)−(match_{—}p%8)}%8 (8)

The number of blocks to store “storeBL” is calculated by, for example, the following expression.

storeBL=(pre_storeB+match_len)/8 (9)

The number of bytes to store “storeB” is calculated by, for example, the following expression.

storeB=(pre_storeB+match_len)%8 (10)

(Step S211) The code generation unit 118 generates a code on the basis of the values calculated in step S210. For example, the code generation unit 118 performs the following operations.

CodeBuff[code_{—}p]=(relativeBL<<3)|shiftB (11)

CodeBuff[code_{—}p+1]=(storeBL<<3)|storeB (12)

The expression (11) sets, in the compressed data 32, a 1-byte value (the first half of the code) indicating the relative number of blocks and the number of bytes to shift. After the value set by the expression (11), a 1-byte value (the second half of the code) indicating the number of blocks to store and the number of bytes to store is set by the expression (12). Further, the number of bytes to store “storeB” is set as the present number of bytes to store “pre_storeB”. Then, the next storage position in the compressed data 32 is advanced by 2 bytes (code_p+=2). Further, the length of the matching symbol string “match_len” is added to the “current_p” (current_p+=match_len).

(Step S212) The match detection unit 113 determines whether compression of the entire compressed data is completed. If the compression is completed, the compression process ends. If the compression is not completed, the process returns to step S202.

In this way, the data may be compressed while using the registers efficiently.

Next, a data decompression process using registers efficiently will be described in detail.

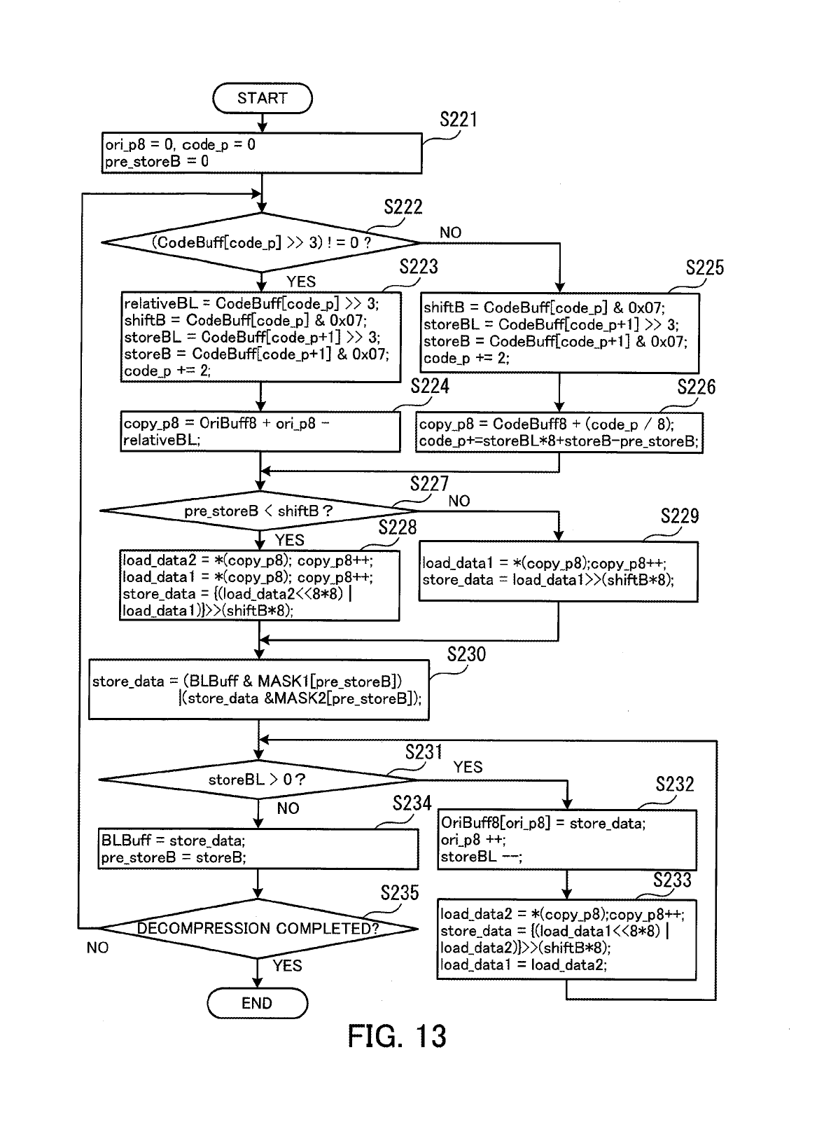

FIG. 13 is a flowchart illustrating an exemplary procedure of a decompression process using registers efficiently.

(Step S221) The code analysis unit 131 initializes parameters. The parameters to be initialized are as follows.

ori_p8=0
code_p=0
pre_storeB=0

The “ori_p8” indicates the address of the next block to be decompressed in the decompressed data 33. The “code_p” indicates the position of the next code to be decompressed.

(Step S222) The code analysis unit 131 determines whether a no-match code is set in the code to be decompressed. For example, the code analysis unit 131 determines whether a no-match code is present on the basis of whether a value obtained by shifting the value (1 byte of the first half of the code) in the compressed data 32 indicated by the “code_p” to the right by 3 bits is “0” ((CodeBuff[code_p]>>3) !=0)). If a no-match code is set, the process proceeds to step S225. If a no-match code is not set, the process proceeds to step S223.

(Step S223) If a no-match code is not set, the code analysis unit 131 acquires the relative number of blocks, the number of bytes to shift, the number of blocks to store, and the number of bytes to store, from the code to be decompressed. For example, the code analysis unit 131 executes the following instructions.

relativeBL=CodeBuff[code_{—}p]>>3 (13)

shiftB=CodeBuff[code_{—}p]&0x07 (14)

storeBL=CodeBuff[code_{—}p+1]>>3 (15)

storeB=CodeBuff[code_{—}p+1]&0x07 (16)

The “>>” is an operator for shifting to the right by the number of bytes specified by the value on the right side. The “&” is the bitwise AND operator. In the expression (13), the “CodeBuff[code_p]>>3” shifts the first byte of the code to the right by 3 bits, so that only the value of the beginning 5 bits remains. The value indicated by the remaining 5 bits is set as the relative number of blocks (relativeBL). In the expression (14), the “CodeBuff[code_p] & 0x07” performs a bitwise AND operation between the value of the first byte of the code and a bit string in which the higher-order 5 bits are “0” and the lower-order 3 bits are “1”. Thus, only the value of the lower-order 3 bits of the first byte of the code remains. The value indicated by the remaining 3 bits is set as the number of bytes to shift (shiftB). In the expression (15), the “CodeBuff[code_p+1]>>3” shifts the second byte of the code to the right by 3 bits, so that only the value of the higher-order 5 bits remains. The value indicated by the remaining 5 bits is set as the number of blocks to store (storeBL). In the expression (16), the “CodeBuff[code_p+1] & 0x07” performs a bitwise AND operation between the value of the second byte of the code and a bit string in which the higher-order 5 bits are “0” and the lower-order 3 bits are “1”. Thus, only the value of the lower-order 3 bits of the second byte of the code remains. The value indicated by the remaining 3 bits is set as the number of bytes to store (storeB). Then, the position indicated by the “code_p” is advanced by 2 bytes (code_p+=2).

(Step S224) The block acquisition unit 132 sets the address of the copy source block in the decompressed data 33 as the copy source address (copy_p8). For example, the block acquisition unit 132 sets the copy source address (copy_p8) by the following calculation.

copy_{—}p8=OriBuff8+ori_{—}p8−relativeBL (17)

The “OriBuff8” is a pointer that indicates the beginning of the area where the decompressed data 33 is stored. Then, the process proceeds to step S227.

(Step S225) If a no-match code is set, the code analysis unit 131 acquires the number of bytes to shift, the number of blocks to store, and the number of bytes to store, from the code to be stored. Then, the position indicated by the “code_p” is advanced by 2 bytes (code_p+=2).

(Step S226) The block acquisition unit 132 sets the address of the copy source block in the compressed data 32 as the copy source address (copy_p8). For example, the block acquisition unit 132 sets the copy source address (copy_p8) by the following calculation.

copy_{—}p8=CodeBuff8+(code_{—}p/8) (18)

The “CodeBuff8” is a pointer that indicates the beginning of the area where the compressed data 32 is stored. Then, the position indicated by the “code_p” is advanced to the position of the next code of the non-matching symbol string. For example, the “code_p” is updated by the following expression.

code_{—}p+=storeBL*8+storeB−pre_storeB (19)

(Step S227) The block acquisition unit 132 determines whether the number of bytes to shift (shiftB) is greater than the present number of bytes to store (pre-storeB). If the number of bytes to shift (shiftB) is greater, the process proceeds to step S228. If present number of bytes to store is equal to or greater than the number of bytes to shift, the process proceeds to step S229.

(Step S228) The block acquisition unit 132 acquires a block at the position indicated by the copy source address (copy_p8) and the next block, and stores the acquired blocks in the load registers 41 and 42. Then, the symbol string generation unit 134 copies, to the merge register 43, a value obtained by shifting by the number of bytes to shift. For example, acquisition of blocks, shifting, and copying are performed by the following instructions.

load_data2=*(copy_{—}p8); copy_{—}p8++ (20)

load_data1=*(copy_{—}p8); copy_{—}p8++ (21)

store_data={(load_data2<<8*8)|load_data1)}>>(shiftB*8) (22)

The “load_data2” indicates data stored in the load register 41. The “load_data1” indicates data stored in the load register 42. The “store_data” indicates data stored in the merge register 43. The “*(copy_p8)” indicates acquiring a block at the position indicated by the “copy_p8”.

The expression (20) stores a copy source block in the load register 41, and increments the address indicated by the “copy_p8” (copy_p8++). Then, the expression (21) stores the next block in the load register 42, and increments the address indicated by the “copy_{—}8” (copy_p8++). Then, the expression (22) merges a value obtained by shifting the data in the load register to the left by 1 block and the value in the load register 42, and sets a value obtained by shifting the merged value to the right by the number of bytes to shift, in the merge register 43. Then, the process proceeds to step S230.

(Step S229) The block acquisition unit 132 acquires a block at the position indicated by the copy source address (copy_p8), and stores the acquired block in the load register 42. Then, the symbol string generation unit 134 copies, to the merge register 43, a value obtained by shifting by the number of bytes to shift. For example, acquisition of a block, shifting, and copying are performed by the following instructions.

load_data1=*(copy_{—}p8); copy_{—}p8++ (23)

store_data=load_data1>>(shiftB*8) (24)

(Step S230) The symbol string generation unit 134 merges the symbol string stored in the merge register 43 and a symbol string in the temporary buffer 44. For example, merging is performed by the following instruction.

store_data=(BLBuff&MASK1[pre_storeB])|(store_data&MASK2[pre_storeB]) (25)

The “BLBuff” indicates data stored in the temporary buffer 44. The “MASK1[ ]” is mask data described below.

$$MASK 1 [ ] = \begin{matrix}\{ 0 \times 00 & 00 & 00 & 00 & 00 & 00 & 00 & 00 , \\ 0 \times FF & 00 & 00 & 00 & 00 & 00 & 00 & 00 , \\ 0 \times FF & FF & 00 & 00 & 00 & 00 & 00 & 00 , \\ 0 \times FF & FF & FF & 00 & 00 & 00 & 00 & 00 , \\ … & & & & & & & \\ 0 \times FF & FF & FF & FF & FF & FF & FF & FF \}\end{matrix}$$

The “MASK1[pre_storeB]” calculates mask data corresponding to the present number of bytes to store (pre-storeB). For example, if the present number of bytes to store (pre_storeB) is “7”, the “MASK1[pre_storeB]” is “0xFF FF FF FF FF FF FF 00”. The “BLBuff & MASK1[pre_storeB]” extracts a symbol string having the number of bytes indicated by the number of bytes to store, from the temporary buffer 44.

The “MASK2[ ]” is mask data described below.

$$MASK 2 [ ] = \begin{matrix}\{ 0 \times FF & FF & FF & FF & FF & FF & FF & FF , \\ 0 \times 00 & FF & FF & FF & FF & FF & FF & FF , \\ … & & & & & & & \\ 0 \times 00 & 00 & 00 & 00 & 00 & 00 & 00 & 00 \}\end{matrix}$$

The “MASK2[pre_storeB]” calculates mask data corresponding to the present number of bytes to store (pre-storeB). For example, if the present number of bytes to store (pre_storeB) is “7”, the “MASK2[pre_storeB]” is “0x00 00 00 00 00 00 00 FF”. The “store_data & MASK2[pre_storeB]” deletes a symbol string having the number of bytes indicated by the number of bytes to store, from the beginning of the merge register 43. Thus, the expression (25) merges the symbol string copied from the load registers 41 and 42 to the merge register 43 and the symbol string in the temporary buffer 44 having the number of bytes indicated by the number of bytes to store.

(Step S231) The symbol string generation unit 134 determines whether the number of blocks to store (storeBL) is greater than 0. If the number of blocks to store is greater than 0, the process proceeds to step S232. If the number of blocks to store is 0 or less, the process proceeds to step S234.

(Step S232) The block output unit 135 adds the symbol string having a length of one block to the decompressed data 33. For example, the block at the beginning of the merge register 43 is added to the decompressed data 33 by the following instruction.

OriBuff8[ori_{—}p8]=store_data (26)

Then, the value of the “ori_p8” is incremented (ori_p8 ++;), and the value of the “storeBL” is decremented (storeBL −−;).

(Step S233) The symbol string generation unit 134 acquires the next copy source block, and merges the acquired block and the previously acquired block. Then, the symbol string generation unit 134 shifts the symbol string in the merge register 43 to the right by the number of bytes to shift. These operations are performed by the following instructions, for example.

load_data2=*(copy_{—}p8); copy_{—}p8++ (27)

store_data={(load_data1<<8*8)|load_data2)}>>(shiftB*8) (28)

load_data1=load_data2 (29)

The expression (27) stores the next block in the load register 41. The expression (28) copies a value obtained by shifting the symbol string in the load register 42 to the left by 1 block and the symbol string in the load register 41 to the merge register 43. Then, a symbol string in the merge register 43 is shifted to the right by the number of bytes to shift. The expression (29) copies the symbol string in the load register 41 to the load register 42. Then, the process returns to step S231.

(Step S234) When the number of blocks to store becomes 0 or less, the symbol string generation unit 134 stores, in the temporary buffer 44, a symbol string starting at the beginning of the merge register 43 and having a length of one block. Further, the symbol string generation unit 134 sets the number of bytes to store (storeB) as the present number of bytes to store (pre_storeB). For example, the following instructions are executed.

BLBuff=store_data (30)

pre_storeB=storeB (31)

(Step S235) The code analysis unit 131 determines whether decompression of the compressed data 32 is completed. For example, the code analysis unit 131 determines that the decompression is completed, when analysis of the last code is completed. If the decompression is completed, the block output unit 135 adds a symbol string starting at the beginning of the temporary buffer 44 and having the number of bytes indicated by the number of bytes to store to the decompressed data 33. Then, the decompression process ends. If the decompression is not completed, the process returns to step S222.

In this way, the data may be decompressed while using the registers efficiently.

As described above, in the second embodiment, since the block to which the copy source block belongs is specified by the relative number of blocks, it is possible to access the decompressed data 33 in units of blocks when decompressing data. This may reduce the number of times of memory access compared to the case of reading the copy source codes in units of codes (bytes). As a result, the time taken to perform data decompression is reduced.

Further, it is possible to decompress data by performing simple operations such as shifting and merging symbol strings that are read in units of blocks. Since information such as the shift amount and the like is contained in the code, there is no need to calculate the shift amount when decompressing data. This makes it possible to decompress data at higher speed.

Further, since the number of blocks to store and the number of bytes to store are contained in the code, it is possible to identify which part of the copied symbol string is decompressed, without performing additional calculations. This reduces the processing load during decompression, and makes it possible to decompress data at high speed.

### (c) Variations

In the second embodiment, a code and a non-matching symbol string may be contained in one block of the compressed data 32. Therefore, codes in the compressed data 32 are read in units of codes. If codes are stored together in one block upon compressing data, it is possible to read codes from the compressed data 32 in units of blocks.

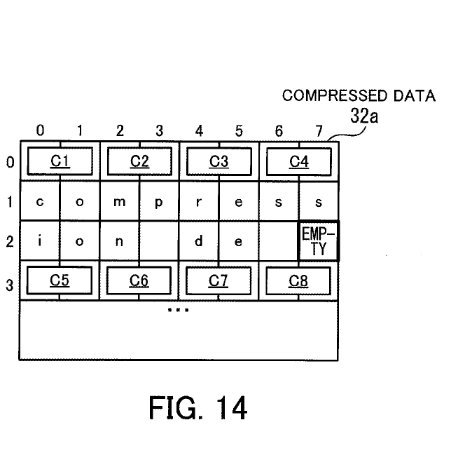

FIG. 14 illustrates an example of compressed data. In compressed data 32a of FIG. 14, four codes C1 through C4 are stored in the block at the address “0”. When decompressing data, the decompression unit 130 reads the block at the address “0”, and stores the read block in a register, for example. Then, the decompression unit 130 sequentially analyzes the codes in the register so as to decompress data. On the other hand, only a non-matching symbol string is stored in the block at the address “1”, and no code is stored therein. When reading the non-matching symbol string from the compressed data 32a upon decompressing data, the non-match symbol string may be read in units of blocks. Since the block storing the non-matching symbol string does not contain unwanted codes, it is possible to read the non-matching symbol string at higher efficiency.

In the second embodiment, the compression unit 110 and the decompression unit 130 are realized by the computer 100. However, the compression unit 110 or the decompression unit 130 may be realized by an electronic circuit.

It is understood that the values set in the code may be changed. For example, the number of blocks from the beginning of the reference section (dictionary) may be used in place of the relative number of blocks. In this case, among blocks contained in the reference section, the beginning of the matching symbol string is contained in a block whose order corresponds to the number of blocks indicated by the code.

In one embodiment, it is possible to decompress data at high speed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A data compression apparatus comprising:
a processor configured to perform a procedure including:
dividing compression target data into a plurality of blocks each including two or more symbols, and examining a sequence of symbols in the data from a beginning thereof so as to search for a second symbol string having a same sequence of symbols as a first symbol string that occurred previously; and
generating a code containing information that specifies a block to which a beginning of the first symbol string belongs, and encoding the second symbol string into the code.

2. The data compression apparatus according to claim 1, wherein the generating includes setting, as the information that specifies the block to which the beginning of the first symbol string belongs, a difference between an address of the block to which the beginning of the first symbol string belongs and an address of a block to which a beginning of the second symbol string belongs.

3. The data compression apparatus according to claim 1, wherein the generating includes storing, in the code of the second symbol string, a shift amount between a position of the beginning of the first symbol string in the block thereof and a position of a beginning of the second symbol string in a block thereof.

4. The data compression apparatus according to claim 1, wherein the generating includes storing, in the code of the second symbol string, a difference between an address of a block to which a beginning of the second symbol string belongs and an address of a block to which a last symbol of the second symbol string belongs.

5. The data compression apparatus according to claim 1, wherein the generating includes storing, in the code of the second symbol string, a difference between a beginning position of a block to which a last symbol of the second symbol string belongs and a position of the last symbol of the second symbol string in the block.

6. The data compression apparatus according to claim 1, wherein the generating includes generating, for a third symbol string for which a symbol string having a same sequence of symbols as the third symbol string is not found in a previously examined portion, a code that contains information indicating that a matching symbol string is not present, and generating compressed data that contains the code of the second symbol string, the code of the third symbol string, and a copy of the third symbol string.

7. The data compression apparatus according to claim 6, wherein the generating includes storing, in the code of the third symbol string, a difference between a position of a beginning of the third symbol string in a block of the data and a position of a beginning of the copy of the third symbol string in one of a plurality of blocks into which the compressed data is divided.

8. The data compression apparatus according to claim 6, wherein the generating includes storing, in the code of the third symbol string, a difference between an address of a block to which a beginning of the third symbol string belongs and an address of a block to which a last symbol of the third symbol string belongs.

9. The data compression apparatus according to claim 6, wherein the generating includes storing, in the code of the third symbol string, a difference between a beginning position of a block to which a last symbol of the third symbol string belongs and a position of the last symbol of the third symbol string in the block.

10. The data compression apparatus according to claim 6, wherein the generating includes dividing the compressed data into a plurality of blocks, and storing the codes and the copy of the third symbol string in different blocks.

11. A data decompression apparatus comprising:
a processor configured to perform a procedure including:
acquiring codes sequentially from a beginning of compressed data,
wherein the compressed data is generated by dividing compression target data into a plurality of blocks each including two or more symbols, examining a sequence of symbols in the data from a beginning thereof so as to search for a second symbol string having a same sequence of symbols as a first symbol string that occurred previously, generating a code containing information that specifies a block to which a beginning of the first symbol string belongs, and encoding the second symbol string into the code; and
decompressing the acquired codes sequentially to original symbol strings, and storing the decompressed symbol strings in a memory in units of blocks,
wherein the decompressing includes acquiring from the memory, when the code of the second symbol string is acquired, one or more blocks starting with a block to which the beginning of the decompressed first symbol string belongs, on the basis of the information that specifies the block to which the beginning of the first symbol string belongs, and copying the first symbol string from the one or more blocks so as to decompress the second symbol string.

12. The data decompression apparatus according to claim 11, wherein:
the code of the second symbol string in the compressed data contains, as the information that specifies the block to which the beginning of the first symbol string belongs, a difference between an address of the block to which the beginning of the first symbol string belongs and an address of a block to which a beginning of the second symbol string belongs; and
the decompressing further includes acquiring, from the memory, the one or more blocks starting with the block at an address preceding the address of the block to which the decompressed second symbol string belongs by the difference.

13. The data decompression apparatus according to claim 11, wherein:
the code of the second symbol string in the compressed data contains a shift amount between a position of the beginning of the first symbol string in the block thereof and a position of a beginning of the second symbol string in a block thereof; and
the decompressing further includes shifting symbols of the first symbol string in the block acquired from the memory by the shift amount so as to merge the first symbol string and an immediately previously decompressed symbol string.

14. The data decompression apparatus according to claim 11, wherein:
the code of the second symbol string in the compressed data contains a difference between an address of a block to which a beginning of the second symbol string belongs and an address of a block to which a last symbol of the second symbol string belongs; and
the decompressing further includes storing, when the second symbol string is decompressed, the number of blocks indicated by the difference in the memory.

15. The data decompression apparatus according to claim 11, wherein:
the code of the second symbol string in the compressed data contains a difference between a beginning position of a block to which a last symbol of the second symbol string belongs and a position of the last symbol of the second symbol string in the block; and
the decompressing further includes holding, when the second symbol string is decompressed, a portion of the decompressed symbol string corresponding to the difference, from an end thereof, and connecting a symbol string that is decompressed on the basis of a next acquired code to an end of the held portion of the symbol string.

16. The data decompression apparatus according to claim 11, wherein:
the compressed data contains a code of a third symbol string for which a symbol string having a same sequence of symbols as the third symbol string is not found in a previously examined portion, and a copy of the third symbol string; and
the decompressing further includes acquiring, when the code of the third symbol string is acquired, the copy of the third symbol string from the compressed data in units of blocks.

17. A data compression method comprising:
dividing, by a processor, compression target data into a plurality of blocks each including two or more symbols, and examining a sequence of symbols in the data from a beginning thereof so as to search for a second symbol string having a same sequence of symbols as a first symbol string that occurred previously; and
generating, by the processor, a code containing information that specifies a block to which a beginning of the first symbol string belongs, and encoding the second symbol string into the code.

18. A data decompression method comprising:
acquiring, by a processor, codes sequentially from a beginning of compressed data,
wherein the compressed data is generated by dividing compression target data into a plurality of blocks each including two or more symbols, examining a sequence of symbols in the data from a beginning thereof so as to search for a second symbol string having a same sequence of symbols as a first symbol string that occurred previously, generating a code containing information that specifies a block to which a beginning of the first symbol string belongs, and encoding the second symbol string into the code; and
decompressing, by the processor, the acquired codes sequentially to original symbol strings, and storing the decompressed symbol strings in a memory in units of blocks,
wherein the decompressing includes acquiring from the memory, when the code of the second symbol string is acquired, one or more blocks starting with a block to which the beginning of the decompressed first symbol string belongs, on the basis of the information that specifies the block to which the beginning of the first symbol string belongs, and copying the first symbol string from the one or more blocks so as to decompress the second symbol string.

19. A computer-readable storage medium storing a computer program, the computer program causing a computer to perform a procedure comprising:
dividing compression target data into a plurality of blocks each including two or more symbols, and examining a sequence of symbols in the data from a beginning thereof so as to search for a second symbol string having a same sequence of symbols as a first symbol string that occurred previously; and
generating a code containing information that specifies a block to which a beginning of the first symbol string belongs, and encoding the second symbol string into the code.

20. A computer-readable storage medium storing a computer program, the computer program causing a computer to perform a procedure comprising:
acquiring codes sequentially from a beginning of compressed data,
wherein the compressed data is generated by dividing compression target data into a plurality of blocks each including two or more symbols, examining a sequence of symbols in the data from a beginning thereof so as to search for a second symbol string having a same sequence of symbols as a first symbol string that occurred previously, generating a code containing information that specifies a block to which a beginning of the first symbol string belongs, and encoding the second symbol string into the code; and
decompressing the acquired codes sequentially to original symbol strings, and storing the decompressed symbol strings in a memory in units of blocks,
wherein the decompressing includes acquiring from the memory, when the code of the second symbol string is acquired, one or more blocks starting with a block to which the beginning of the decompressed first symbol string belongs, on the basis of the information that specifies the block to which the beginning of the first symbol string belongs, and copying the first symbol string from the one or more blocks so as to decompress the second symbol string.
